(19) United States
(12) Patent Application Publication
(10) Pub. No.: US 2026/0136766 A1
(43) Pub. Date: May 14, 2026

(54) DISPLAY APPARATUS

(71) Applicant: Samsung Display Co., Ltd., Yongin-si (KR)

(72) Inventor: Jonghyun Choi, Yongin-si (KR)

(21) Appl. No.: 19/014,709

(22) Filed: Jan. 9, 2025

(30) Foreign Application Priority Data
May 23, 2024 (KR) 10-2024-0067257

(51) Int. Cl. H10K 59/121; H10D 86/40

(52) U.S. Cl. CPC H10K 59/1213; H10D 86/441

(57) ABSTRACT

A display apparatus in which a space may be efficiently utilized is provided. The display apparatus includes a first semiconductor layer on a substrate, a first gate insulating layer covering the first semiconductor layer, a first gate layer on the first gate insulating layer, a first interlayer insulating layer covering the first gate layer, a second gate layer on the first interlayer insulating layer, a second gate insulating layer covering the second gate layer, a second semiconductor layer on the second gate insulating layer, and a lower connection electrode layer between the second gate insulating layer and the second semiconductor layer and including a first lower connection electrode and a second lower connection electrode, where the first lower connection electrode is in contact with the first semiconductor layer, and the second lower connection electrode is in contact with the second gate layer.

### CROSS-REFERENCE TO RELATED APPLICATION

The present application claims priority to and the benefit of Korean Patent Application No. 10-2024-0067257, filed on May 23, 2024, in the Korean Intellectual Property Office, the entire disclosure of which is incorporated herein by reference.

### BACKGROUND

### 1. Field

One or more embodiments relate to a display apparatus, and for example, to a display apparatus in which a space may be efficiently utilized.

### 2. Description of the Related Art

A display apparatus includes a display element and a pixel circuit that is electrically connected to the display element. The pixel circuit includes a transistor, which receives electrical signals through wirings arranged (positioned) beneath (below) the transistor. To facilitate this, bridge electrodes are placed (arranged) on the transistor, connecting the semiconductor layer of the transistor to the wirings arranged (located) below the transistor.

### SUMMARY

However, in a display apparatus according to the related art, the placement of bridge electrodes are arranged on the same layer as the may lead to inefficient space utilization. For example, this configuration can limit the design flexibility (freedom) of the display apparatus.

Aspects of one or more embodiments are directed toward a display apparatus that efficiently utilize space. However, such aspects are merely examples, and the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a first semiconductor layer arranged on a substrate, a first gate insulating layer covering the first semiconductor layer, a first gate layer arranged on the first gate insulating layer, a first interlayer insulating layer covering the first gate layer, a second gate layer arranged on the first interlayer insulating layer, a second gate insulating layer covering the second gate layer, a second semiconductor layer arranged on the second gate insulating layer, a third gate insulating layer covering the second semiconductor layer, a third gate layer arranged on the third gate insulating layer, a second interlayer insulating layer covering the third gate layer, a first connection electrode layer arranged on the second interlayer insulating layer, and a lower connection electrode layer arranged between the second gate insulating layer and the second semiconductor layer and including a first lower connection electrode and a second lower connection electrode, where the first lower connection electrode is in contact with the first semiconductor layer through a contact hole formed in the first gate insulating layer, the first interlayer insulating layer, and the second gate insulating layer, and the second lower connection electrode is in contact with the second gate layer through a contact hole formed in the second gate insulating layer.

In some embodiments, the lower connection electrode layer may be in direct contact with the second semiconductor layer.

In some embodiments, the second semiconductor layer may cover at least a portion of the lower connection electrode layer.

In some embodiments, the third gate insulating layer may cover the second semiconductor layer and the lower connection electrode layer.

In some embodiments, the first lower connection electrode may be electrically connected to the second semiconductor layer and the first semiconductor layer.

In some embodiments, the second lower connection electrode may be electrically connected to the second semiconductor layer and the second gate layer.

In some embodiments, the first connection electrode layer may include a connection electrode that is in contact with the second semiconductor layer through a contact hole formed in the third gate insulating layer and the second interlayer insulating layer.

In some embodiments, the connection electrode may be electrically connected to the second semiconductor layer.

In some embodiments, the connection electrode may be in contact with the first gate layer through a contact hole formed in the first interlayer insulating layer, the second gate insulating layer, the third gate insulating layer, and the second interlayer insulating layer.

In some embodiments, the first semiconductor layer may include a silicon semiconductor, and the second semiconductor layer may include an oxide semiconductor.

According to one or more embodiments, a display apparatus includes a first semiconductor layer arranged on a substrate, a first gate insulating layer covering the first semiconductor layer, a first gate layer arranged on the first gate insulating layer, a first interlayer insulating layer covering the first gate layer, a second gate layer arranged on the first interlayer insulating layer, a second gate insulating layer covering the second gate layer, a second semiconductor layer arranged on the second gate insulating layer, a third gate insulating layer covering the second semiconductor layer, a third gate layer arranged on the third gate insulating layer, a second interlayer insulating layer covering the third gate layer, a first connection electrode layer arranged on the second interlayer insulating layer, and a lower connection electrode layer arranged between the second gate insulating layer and the second semiconductor layer and including a lower connection electrode, wherein the lower connection electrode is in contact with the first gate layer through a contact hole formed in the first interlayer insulating layer and the second interlayer insulating layer.

In some embodiments, the lower connection electrode layer may be in direct contact with the second semiconductor layer.

In some embodiments, the second semiconductor layer may cover at least a portion of the lower connection electrode layer.

In some embodiments, the third gate insulating layer may cover the second semiconductor layer and the lower connection electrode layer.

In some embodiments, the lower connection electrode may be electrically connected to the second semiconductor layer and the first gate layer.

In some embodiments, the first connection electrode layer may include a first connection electrode and a second connection electrode that are in contact with the second semiconductor layer through contact holes formed in the third gate insulating layer and the second interlayer insulating layer.

In some embodiments, the first connection electrode and the second connection electrode may be electrically connected to the second semiconductor layer.

In some embodiments, the first connection electrode may be in contact with the first semiconductor layer through a contact hole formed in the first gate insulating layer, the first interlayer insulating layer, the second gate insulating layer, the third gate insulating layer, and the second interlayer insulating layer.

In some embodiments, the second connection electrode may be in contact with the second gate layer through a contact hole formed in the second gate insulating layer, the third gate insulating layer, and the second interlayer insulating layer.

In some embodiments, the first semiconductor layer may include a silicon semiconductor, and the second semiconductor layer may include an oxide semiconductor.

According to one or more embodiments, an electronic apparatus may include one of the display apparatuses described above.

These and/or other aspects will become apparent and more readily appreciated from the following detailed description of one or more embodiments, the accompanying drawings, and claims.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a schematic plan view of a display apparatus according to one or more embodiments;

FIG. 2 is an equivalent circuit diagram of a pixel of a display apparatus according to one or more embodiments;

FIG. 3 is a schematic layout view showing the positions of transistors, a storage capacitor, and/or the like in pixels of a display apparatus according to one or more embodiments;

FIG. 4-11 are schematic layout views of elements, such as transistors and a storage capacitor, for each layer of a display apparatus shown in FIG. 3;

FIG. 12 is a schematic cross-sectional view of a display apparatus of FIG. 3, taken along the line I-I′ of FIG. 3;

FIG. 13 is a schematic cross-sectional view of the display apparatus of FIG. 3, taken along the line II-II′ of FIG. 3;

FIG. 14 is a schematic cross-sectional view of the display apparatus of FIG. 3, taken along the line III-III′ of FIG. 3;

FIG. 15 is a schematic layout view showing the positions of transistors, a storage capacitor, and/or the like in pixels of a display apparatus according to one or more embodiments;

FIGS. 16 and 17 are portions of schematic layout views of elements such as transistors and a storage capacitor, for each layer, of FIG. 15;

FIG. 18 is a schematic cross-sectional view of a display apparatus of FIG. 15, taken along the line IV-IV′ of FIG. 15;

FIG. 19 is a schematic cross-sectional view of the display apparatus of FIG. 15, taken along the line V-V′ of FIG. 15; and

FIG. 20 is a schematic cross-sectional view of the display apparatus of FIG. 15, taken along the line VI-VI′ of FIG. 15.

### DETAILED DESCRIPTION

Reference will now be made in more detail to one or more embodiments, examples of which are illustrated in the accompanying drawings, where like reference numerals refer to like elements throughout, and duplicative descriptions thereof may not be provided. In this regard, the present embodiments may have different forms and should not be construed as being limited to the descriptions set forth herein. Accordingly, one or more embodiments are merely described in more detail, by referring to the drawings, to explain aspects of the present description. As used herein, the term “and/or” includes any and all combinations of one or more of the associated listed items. Throughout the disclosure, the expression “at least one of a, b or c” indicates only a, only b, only c, both (e.g., simultaneously) a and b, both (e.g., simultaneously) a and c, both (e.g., simultaneously) b and c, all of a, b, and c, or variations thereof.

As the disclosure allows for one or more suitable changes and numerous embodiments, certain embodiments will be illustrated in the drawings and described in the written description. Effects and features of the disclosure, and methods for achieving them will be clarified with reference to one or more embodiments described in more detail later in more detail with reference to the drawings. However, the disclosure is not limited to the following embodiments and may be embodied in one or more suitable forms.

While such terms as “first” and “second” may be used to describe one or more suitable components, such components must not be limited to the above terms. The above terms are used to distinguish one component from another.

The singular forms “a,” “an,” and “the” as used herein are intended to include the plural forms as well unless the context clearly indicates otherwise.

It will be understood that when an element or layer is referred to as being “on”, “connected to”, “coupled to”, or “adjacent to” another element or layer, it can be directly on, connected to, coupled to, or adjacent to the other element or layer, or one or more intervening elements or layers may be present. In contrast, when an element or layer is referred to as being “directly on,” “directly connected to”, “directly coupled to”, or “immediately adjacent to” another element or layer, there are no intervening elements or layers present.

In the present specification, “A and/or B” refers to A or B, or A and B. In the present specification, “at least one of A and B” refers to A or B, or A and B.

In the present specification, if (e.g., when) one or more suitable elements such as a layer, a region, a plate, and/or the like are arranged “on” another element, not only the elements may be arranged “directly on” the other element, but another element may be arranged therebetween.

It will be understood that if (e.g., when) a layer, region, or component is referred to as being “connected” to another layer, region, or component, it may be “directly connected” to the other layer, region, or component or may be “indirectly connected” to the other layer, region, or component with other layer, region, or component interposed therebetween. For example, it will be understood that if (e.g., when) a layer, region, or element is referred to as being “electrically connected” to another layer, region, or element, it may be “directly electrically connected” to the other layer, region, or element or may be “indirectly electrically connected” to the other layer, region, or element with another layer, region, or element interposed therebetween.

The x-axis, the y-axis and the z-axis are not limited to three axes of the rectangular coordinate system, and may be interpreted in a broader sense. For example, the x-axis, the y-axis, and the z-axis may be normal (e.g., perpendicular) to one another, or may represent different directions that are not normal (e.g., perpendicular) to one another.

Hereinafter, embodiments will be described with reference to the accompanying drawings, where like reference numerals refer to like elements throughout, and duplicative descriptions thereof may not be provided and a repeated description thereof is omitted. Sizes of elements in the drawings may be exaggerated or reduced for convenience of explanation. In some embodiments, the size and thickness of each element shown in the drawings are arbitrarily represented for convenience of description, and thus, the disclosure is not necessarily limited thereto.

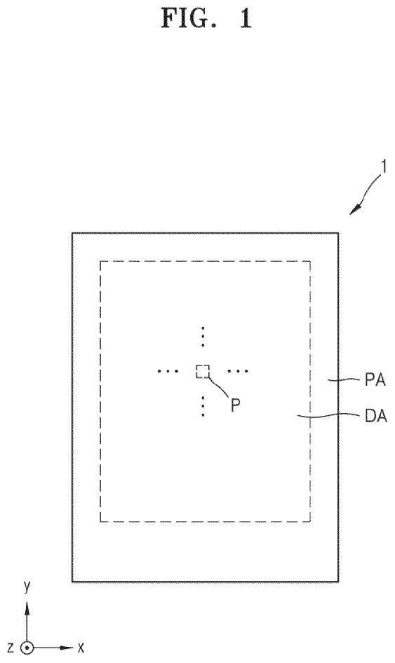

FIG. 1 is a schematic plan view of a display apparatus 1 according to one or more embodiments.

In one or more embodiments, an electronic apparatus may include the display apparatus described below. In other words, the display apparatus according to an embodiment may be implemented as an electronic apparatus such as a smartphone, a mobile phone, a navigation device, a game device, a television (TV), a vehicle head unit, a notebook computer, a laptop computer, a tablet computer, a personal media player (PMP), or a personal digital assistant (PDA). In an embodiment, the electronic apparatus may be a flexible apparatus.

As shown in FIG. 1, the display apparatus 1 may include a display area DA and a peripheral area PA, where a plurality of pixels P are arranged in the display area DA, and the peripheral area PA is outside the display area DA. For example, the peripheral area PA may be around (e.g., surround) the display area DA entirely.

Each pixel P of the display apparatus 1 is configured to emit light of a preset color. The display apparatus 1 may be configured to display images utilizing light emitted from the pixels P. In some embodiments, each pixel P may be configured to emit red, green, or blue light. As shown in FIG. 1, the display area DA may have a polygonal shape including a quadrangular shape. In some embodiments, the display area DA may have a rectangular shape in which a horizontal length thereof is less than a vertical length, a rectangular shape in which a horizontal length thereof is greater than a vertical length, or a square shape. In one or more embodiments, the display area DA may have one or more suitable shapes, such as an elliptical shape or a circular shape.

The peripheral area PA may be a non-display area in which the pixels PX are not arranged. A driver and/or the like that provides electric signals or power to the pixels PX may be arranged in the peripheral area PA. A plurality of pads may be arranged in the peripheral area PA, where the pads are a region to which electronic elements or a printed circuit board may be electrically connected. The pads may be apart from each other in the peripheral area PA and electrically connected to a printed circuit board or an integrated circuit element.

Hereinafter, although an organic light-emitting display apparatus is described as an example of the display apparatus 1 according to one or more embodiments, the display apparatus 1 is not limited thereto. In one or more embodiments, the display apparatus 1 may be an inorganic light-emitting display apparatus or a quantum-dot light-emitting display apparatus. In some embodiments, an emission layer of the display element of the display apparatus 1 may include an organic material or an inorganic material. In addition, the display apparatus 1 may include the emission layer and a quantum-dot layer arranged on a path of light emitted from the emission layer.

For example, the pixel P may include the display element, such as an organic light-emitting diode OLED and be electrically connected to outer circuits arranged in the peripheral area PA. A scan driving circuit, an emission control driving circuit, a driving power supply line, an electrode power supply line, and/or the like may be arranged in the peripheral area PA. The scan driving circuit may provide scan signals to the pixel through a scan line. The emission control driving circuit may provide emission control signals to the pixel through an emission control line.

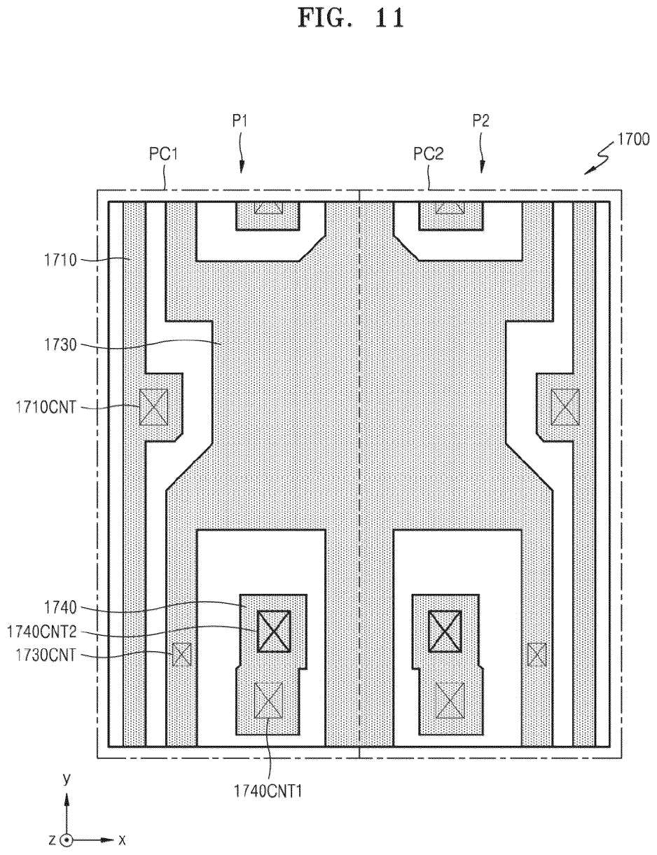

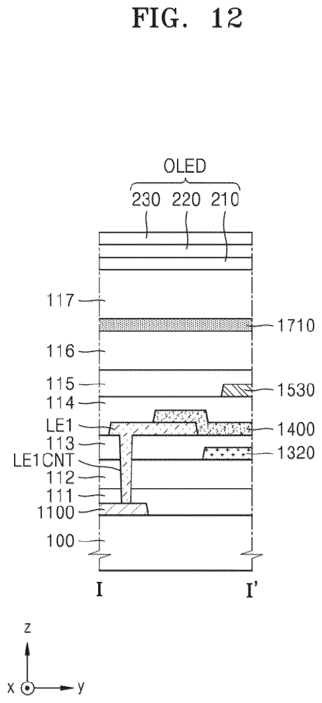

As described above, a printed circuit board or an integrated circuit element may be electrically connected to the pads, and signals of a controller, or power may be transferred to the display apparatus 1 through the printed circuit board or the integrated circuit element. In some embodiments, control signals generated by the controller may be respectively transferred to the driving circuits. In addition, the controller may be configured to transfer a first power voltage ELVDD to the driving power supply line and transfer a second power voltage ELVSS to an electrode power supply line. The first power voltage ELVDD (or a driving voltage) may be transferred to each pixel through a driving voltage supply line 1730 (see FIG. 11) connected to the driving power supply line, and the second power voltage ELVSS (or a common voltage) may be transferred to an opposite electrode 230 (see FIG. 12) of the pixel connected to the electrode power supply line. The electrode power supply line may have a loop shape having one open side and have a shape partially around (e.g., surrounding) the display area DA.

The controller may be configured to generate data signals, and the generated data signals may be transferred to the pixel through a data line 1710 (see FIG. 11).

For reference, a “line” may refer to a “wiring”. This is applicable to one or more embodiments and modifications thereof.

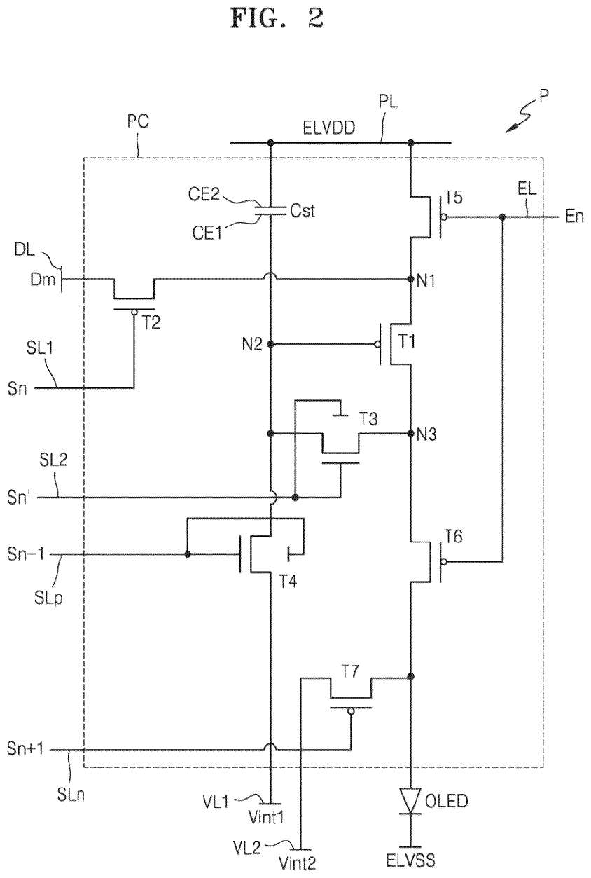

FIG. 2 is an equivalent circuit diagram of a pixel P of the display apparatus 1 according to one or more embodiments. One pixel P may include a pixel circuit PC and an organic light-emitting diode OLED electrically connected to the pixel circuit PC.

As shown in FIG. 2, the pixel circuit PC may include a plurality of transistors T1, T2, T3, T4, T5, T6, and T7, and a storage capacitor Cst. The plurality of transistors T1, T2, T3, T4, T5, T6, and T7, and the storage capacitor Cst may be connected to signal lines SL1, SL2, SLp, SLn, EL, and DL, a first initialization voltage line VL1, a second initialization voltage line VL2, and a driving voltage line PL. At least one of the lines (e.g., the driving voltage line PL) may be shared by the pixels P adjacent to each other.

The plurality of transistors T1, T2, T3, T4, T5, T6, and T7 may include a driving transistor T1, a switching transistor T2, a compensation transistor T3, a first initialization transistor T4, an operation control transistor T5, an emission control transistor T6, and a second initialization transistor T7.

The organic light-emitting diode OLED may include a first electrode (e.g., a pixel electrode) and a second electrode (e.g., an opposite electrode). The first electrode of the organic light-emitting diode OLED may be connected to the driving transistor T1 through the emission control transistor T6 to receive a driving current, and the second electrode may receive the second power voltage ELVSS. The organic light-emitting diode OLED may be configured to generate light of brightness corresponding to the driving current.

Some of the plurality of transistors T1, T2, T3, T4, T5, T6, and T7 may be n-channel metal oxide semiconductor (NMOS) field-effect transistors (n-channel MOSFETs), and the rest may be p-channel metal oxide semiconductor (PMOS) field-effect transistors (p-channel MOSFETs). In some embodiments, among the plurality of transistors T1, T2, T3, T4, T5, T6, and T7, the compensation transistor T3 and the first initialization transistor T4 may be n-channel MOSFET (NMOS), and the rest may be p-channel MOSFET (PMOS). In one or more embodiments, among the plurality of transistors T1, T2, T3, T4, T5, T6, and T7, the compensation transistor T3, the first initialization transistor T4, and the second initialization transistor T7 may be n-channel MOSFETs (NMOSs), and the rest may be p-channel MOSFETs (PMOSs). In one or more embodiments, all of the plurality of transistors T1, T2, T3, T4, T5, T6, and T7 may be NMOSs or PMOSs. The plurality of transistors T1, T2, T3, T4, T5, T6, and T7 may each include amorphous silicon or polycrystalline silicon. In some embodiments, if (e.g., when) needed, a transistor (e.g., an NMOS) may include an oxide semiconductor. Hereinafter, for convenience of description, the case, where the compensation transistor T3 and the first initialization transistor T4 are NMOSs including an oxide semiconductor and the rest are PMOSs, is described.

The signal lines may include a first scan line SL1, a second scan line SL2, a previous scan line SLp, a next scan line SLn, an emission control line EL, and a data line DL, where the first scan line SL1 is configured to transfer a first scan signal Sn, the second scan line SL2 is configured to transfer a second scan signal Sn′, the previous scan line SLp is configured to transfer a previous scan signal Sn−1 to the first initialization transistor T4, the next scan line SLn is configured to transfer a next scan signal Sn+1 to the second initialization transistor T7, the emission control line En is configured to transfer an emission control signal En to the operation control transistor T5 and the emission control transistor T6, and the data line DL crosses the first scan line SL1 and is configured to transfer a data signal Dm.

The driving voltage line PL may be configured to transfer the driving voltage ELVDD to the driving transistor T1, the first initialization voltage line VL1 may be configured to transfer a first initialization voltage Vint1 initializing the driving transistor T1, and the second initialization voltage line VL2 may be configured to transfer a second initialization voltage Vint2 initializing the first electrode of the organic light-emitting diode OLED.

A driving gate electrode of the driving transistor T1 may be connected to the storage capacitor Cst through a second node N2, one of a source region and a drain region of the driving transistor T1 may be connected to the driving voltage line PL through the operation control transistor T5 via a first node N1, and the other of the source region and the drain region of the driving transistor T1 may be connected to the first electrode (e.g., the pixel electrode) of the organic light-emitting diode OLED through the emission control transistor T6 via a third node N3. The driving transistor T1 may be configured to receive a data signal Dm and supply the driving current to the organic light-emitting diode OLED according to a switching operation of the switching transistor T2. For example, the driving transistor T1 may be configured to control the amount of current flowing from the first node N1 to the organic light-emitting diode OLED, in response to a voltage applied to the second node N2 and changed by a data signal Dm, the first node N1 being electrically connected to the driving voltage line PL.

A switching gate electrode of the switching transistor T2 may be connected to the first scan line SL1 configured to transfer the first scan signal Sn, one of a source region and a drain region of the switching transistor T2 may be connected to the data line DL, and the other of the source region and the drain region of the switching transistor T2 may be connected to the driving transistor T1 through the first node N1 and connected to the driving voltage line PL through the operation control transistor T5. The switching transistor T2 may be configured to transfer a data signal Dm from the data line DL to the first node N1 in response to a voltage applied to the first scan line SL1. For example, the switching transistor T2 may perform a switching operation of being turned on according to the first scan signal Sn transferred through the first scan line SL1 and transferring a data signal Dm to the driving transistor T1 through the first node N1, the data signal Dm being transferred through the data line DL.

A compensation gate electrode of the compensation transistor T3 is connected to the second scan line SL2. One of a source region and a drain region of the compensation transistor T3 may be connected to the first electrode of the organic light-emitting diode OLED through the emission control transistor T6 via the third node N3. The other of the source region and the drain region of the compensation transistor T3 may be connected to a first capacitor electrode CE1 of the storage capacitor Cst, and the driving gate electrode of the driving transistor T1 through the second node N2. The compensation transistor T3 may diode-connect the driving transistor T1 by being turned on according to the second scan signal Sn′ received through the second scan line SL2.

A first initialization gate electrode of the first initialization transistor T4 may be connected to the previous scan line SLp. One of a source region and a drain region of the first initialization transistor T4 may be connected to the first initialization voltage line VL1. The other of the source region and the drain region of the first initialization transistor T4 may be connected to the first capacitor electrode CE1 of the storage capacitor Cst, and the driving gate electrode of the driving transistor T1 through the second node N2. The first initialization transistor T4 may be configured to apply the first initialization voltage Vint1 from the first initialization voltage line VL1 to the second node N2 according to a voltage applied to the previous scan line SLp. For example, the first initialization transistor T4 may be turned on according to the previous scan signal Sn−1 received through the previous scan line SLp and may perform an initialization operation of initializing the voltage of the driving gate voltage of the driving transistor T1 by transferring the first initialization voltage Vint1 to the driving gate electrode of the driving transistor T1.

An operation control gate electrode of the operation control transistor T5 may be connected to the emission control line EL, one of a source region and a drain region of the operation control transistor T5 may be connected to the driving voltage line PL, and the other of the source region and the drain region of the operation control transistor T5 may be connected to the driving transistor T1 and the switching transistor T2 through the first node N1.

An emission control gate electrode of the emission control transistor T6 may be connected to the emission control line EL, one of a source region and a drain region of the emission control transistor T6 may be connected to the driving transistor T1 and the compensation transistor T3 through the third node N3, and the other of the source region and the drain region of the emission control transistor T6 may be electrically connected to the first electrode (the pixel electrode) of the organic light-emitting diode OLED.

The operation control transistor T5 and the emission control transistor T6 may be concurrently (e.g., simultaneously) turned on according to an emission control signal En transferred through the emission control line EL, the driving voltage ELVDD is transferred to the organic light-emitting diode OLED, and the driving current flows through the organic light-emitting diode OLED.

A second initialization gate electrode of the second initialization transistor T7 may be connected to the next scan line SLn, one of a source region and a drain region of the second initialization transistor T7 may be connected to the first electrode (the pixel electrode) of the organic light-emitting diode OLED, and the other of the source region and the drain region of the second initialization transistor T7 may be electrically connected to the second initialization voltage line VL2 to receive the second initialization voltage Vint2. The second initialization transistor T7 is turned on according to the next scan signal Sn+1 transferred through the next scan line SLn and initializes the first electrode (the pixel electrode) of the organic light-emitting diode OLED. The next scan line SLn may be the same as the first scan line SL1. In this case, the relevant scan line may be configured to transfer the same electrical signals with a time difference, and thus, may serve as the first scan line SL1 and the next scan line SLn. For example, the next scan line SLn may be a first scan line of a pixel which is a pixel adjacent to the pixel P shown in FIG. 2 and electrically connected to the data line DL.

As shown in FIG. 2, the second initialization transistor T7 may be connected to the next scan line SLn. However, the disclosure is not limited thereto and the second initialization transistor T7 may be connected to the emission control line EL and driven according to an emission control signal En.

The storage capacitor Cst may include the first capacitor electrode CE1 and a second capacitor electrode CE2. The first capacitor electrode CE1 of the storage capacitor Cst is connected to the driving gate electrode of the driving transistor T1 through the second node N2, and the second capacitor electrode CE2 of the storage capacitor Cst is connected to the driving voltage line PL. The storage capacitor Cst may be configured to store charge corresponding to a difference between a voltage of the driving gate of the driving transistor T1 and the driving voltage ELVDD.

A specific operation of each pixel P according to one or more embodiments is described in more detail.

When the previous scan signal Sn−1 is supplied through the previous scan line SLp during an initialization period, the first initialization transistor T4 is turned on according to the previous scan signal Sn−1, and the driving transistor T1 is initialized by the first initialization voltage Vint1 supplied from the first initialization voltage line VL1.

If (e.g., when) the first scan signal Sn and the second scan signal Sn′ are supplied through the first scan line SL1 and the second scan line SL2 during a data programming period, the switching transistor T2 and the compensation transistor T3 are turned on according to the first scan signal Sn and the second scan signal Sn'. In this case, the driving transistor T1 is diode-connected and forward-biased by the compensation transistor T3 that is turned on. Then, a compensation voltage Dm+Vth (where Vth may have a (−) value) is applied to the driving gate electrode G1 of the driving transistor T1, where the compensation voltage Dm+Vth is a voltage reduced by a threshold voltage Vth of the driving transistor T1 from a data signal Dm supplied from the data line DL. The driving voltage ELVDD and the compensation voltage Dm+Vth are respectively applied to two opposite ends of the storage capacitor Cst, and charge corresponding to a difference between voltages of the two opposite ends is stored in the storage capacitor Cst.

During an emission period, the operation control transistor T5 and the emission control transistor T6 are turned on according to an emission control signal En supplied from the emission control line EL. The driving current corresponding to a voltage difference between the voltage of the driving gate electrode G1 of the driving transistor T1 and the driving voltage ELVDD occurs, and the driving current is supplied to the organic light-emitting diode OLED through the emission control transistor T6.

As described above, some of the plurality of transistors T1, T2, T3, T4, T5, T6, and T7 may include an oxide semiconductor. In some embodiments, the compensation transistor T3 and the first initialization transistor T4 may include an oxide semiconductor.

Because polycrystalline silicon has high reliability, it is possible to accurately control the flow of an intended current. Accordingly, the driving transistor T1 directly influencing the brightness of the display apparatus may include a semiconductor layer including polycrystalline silicon having high reliability, and thus, a high-resolution display apparatus may be implemented through this configuration. Because an oxide semiconductor has high carrier mobility and a low leakage current, a voltage drop is not large even if (e.g., when) a driving time is long. For example, in the oxide semiconductor, because a color change of an image according to a voltage drop is not significant even when the display apparatus is driven in low frequencies, the display apparatus may be driven in low frequencies. Accordingly, by allowing the compensation transistor T3 and the first initialization transistor T4 to include an oxide semiconductor, a display apparatus in which the occurrence of a leakage current is prevented or reduced, and concurrently (e.g., simultaneously), with a reduced power consumption may be implemented.

Because the oxide semiconductor is sensitive to light, a change in the amount of current may occur due to externa light. Accordingly, external light may be absorbed or reflected by disposing a metal layer under the oxide semiconductor. Accordingly, as shown in FIG. 2, gate electrodes of each of the compensation transistor T3 and the first initialization transistor T4 may be respectively arranged on and under the oxide semiconductor layer. For example, in a direction (e.g., a z axis direction) normal (e.g., perpendicular) to the substrate 100 (see FIG. 12), the metal layer arranged under the oxide semiconductor may overlap the oxide semiconductor (in a plan view).

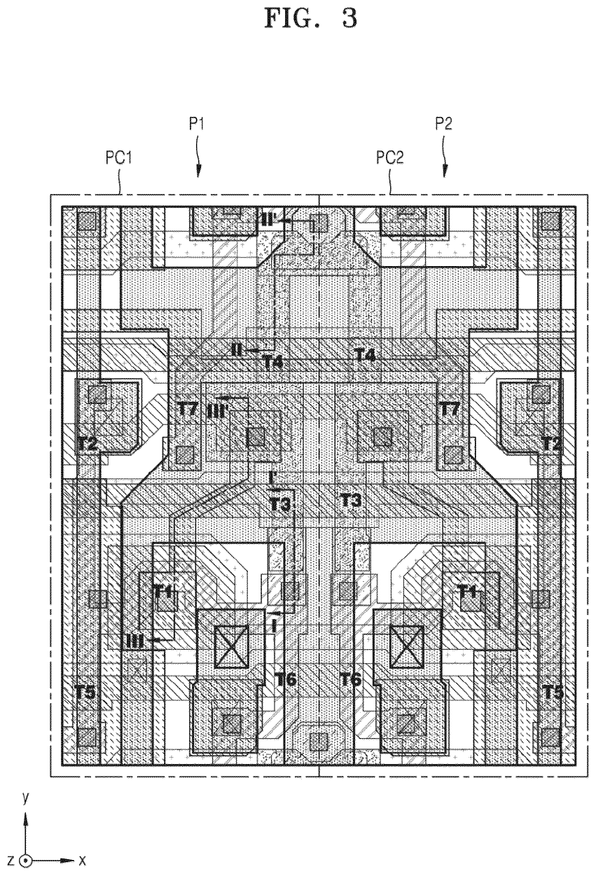

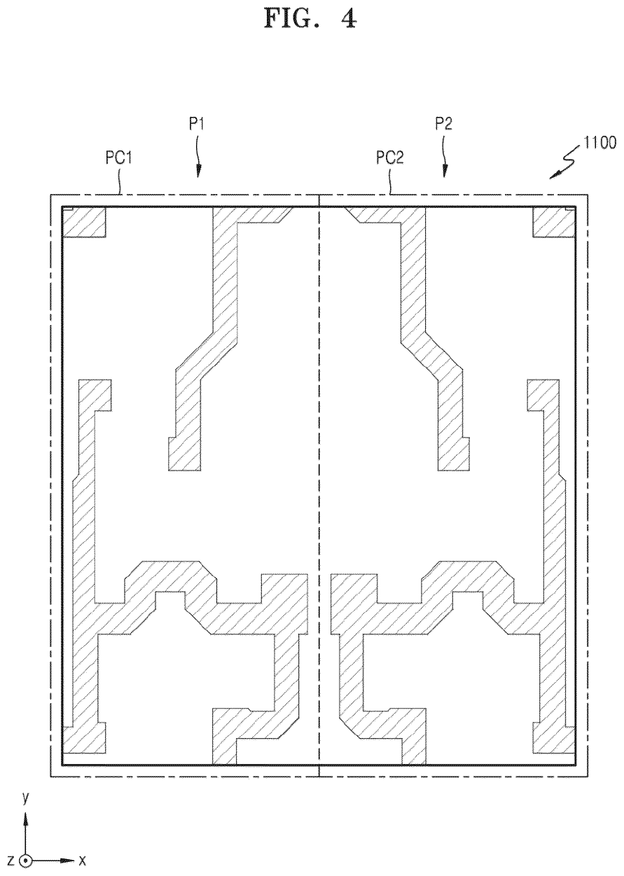

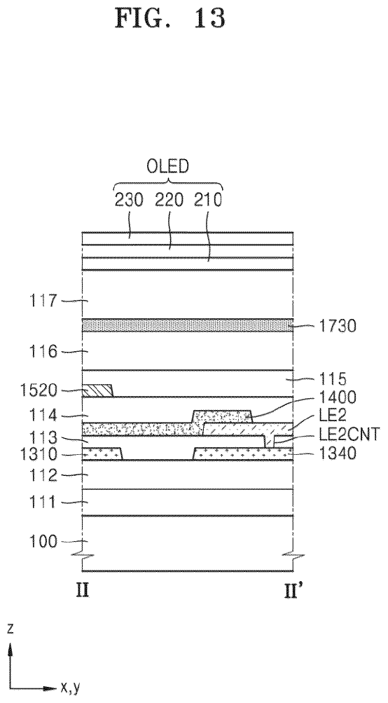

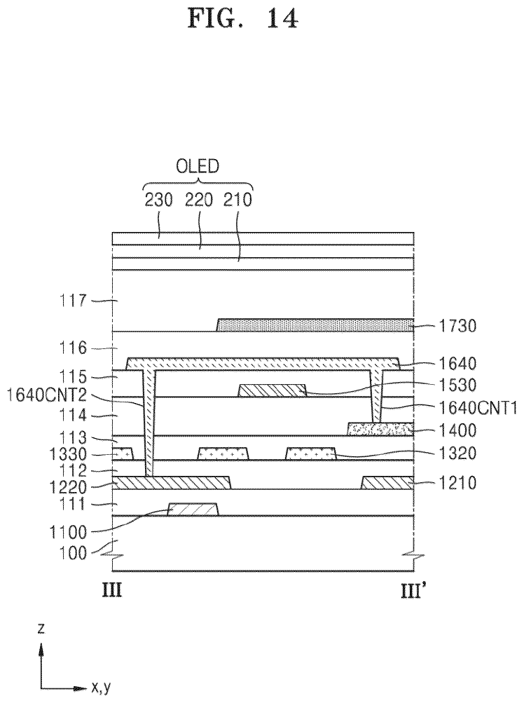

FIG. 3 is a schematic layout view showing the positions of the transistors T1, T2, T3, T4, T5, T6, T7, the storage capacitor Cst, and/or the like in the pixels of the display apparatus 1 according to one or more embodiments. FIGS. 4 to 11 are schematic layout views of elements such as the transistors T1, T2, T3, T4, T5, T6, T7, the storage capacitor Cst, for each layer, of a display apparatus shown in FIG. 3. FIG. 12 is a schematic cross-sectional view of the display apparatus 1 of FIG. 3, taken along the line I-I′ of FIG. 3. FIG. 13 is a schematic cross-sectional view of the display apparatus 1 of FIG. 3, taken along the line II-II′ of FIG. 3. FIG. 14 is a schematic cross-sectional view of the display apparatus 1 of FIG. 3, taken along the line III-III′ of FIG. 3.

As shown in the drawings, the display apparatus 1 may include a first pixel P1 and a second pixel P2 adjacent to each other. The first pixel P1 and the second pixel P2 may be symmetrical to each other with respect to a virtual line as shown in FIG. 3 and/or the like. The disclosure is not limited thereto, and the first pixel P1 and the second pixel P2 may have the same structure, not a symmetrical structure (e.g., the first pixel P1 does not have a structure that mirrors the second pixel P2). The first pixel P1 may include a first pixel circuit PC1, and the second pixel P2 may include a second pixel circuit PC2. Hereinafter, for convenience of description, although some of conductive patterns are described based on the first pixel circuit PC1, these conductive patterns may be symmetrically arranged in the second pixel circuit PC2.

The display apparatus 1 may include the substrate 100 (see FIG. 12). Because the display apparatus 1 includes the substrate 100, it may be understood that the substrate 100 includes the display area DA and the peripheral area PA described above. Various elements of the display apparatus 1 may be arranged on the substrate 100.

The substrate 100 may include glass, metal, and/or polymer resin. The substrate 100 may be flexible or bendable. In this case, the substrate 100 may include polymer resin, such as polyethersulphone, polyacrylate, polyetherimide, polyethylene naphthalate, polyethylene terephthalate, polyphenylene sulfide, polyarylate, polyimide, polycarbonate, and/or cellulose acetate propionate. The substrate 100 may have a multi-layered structure including two layers each including the polymer resin, and/or a barrier layer including an inorganic material, such as silicon oxide (SiO_{x,} e.g., SiO₂), silicon nitride (SiNₓ, e.g., Si₃N₄), and/or silicon oxynitride (SiOₓN_{y}), therebetween. However, one or more suitable modifications may be made.

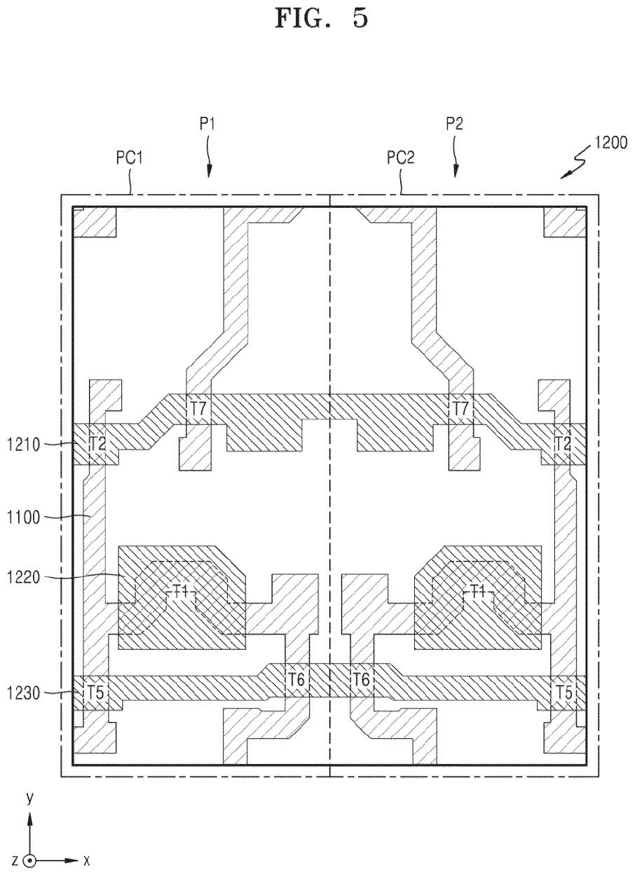

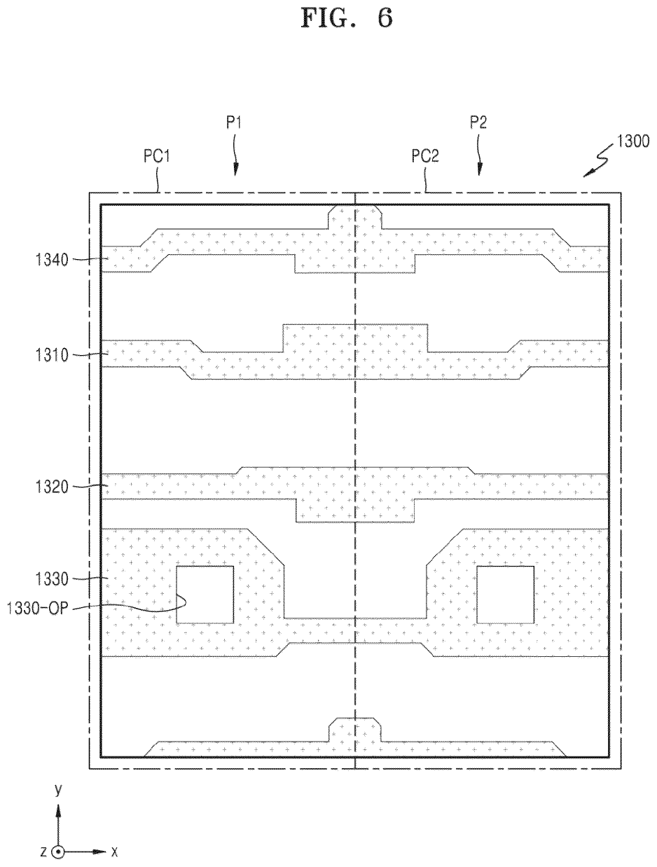

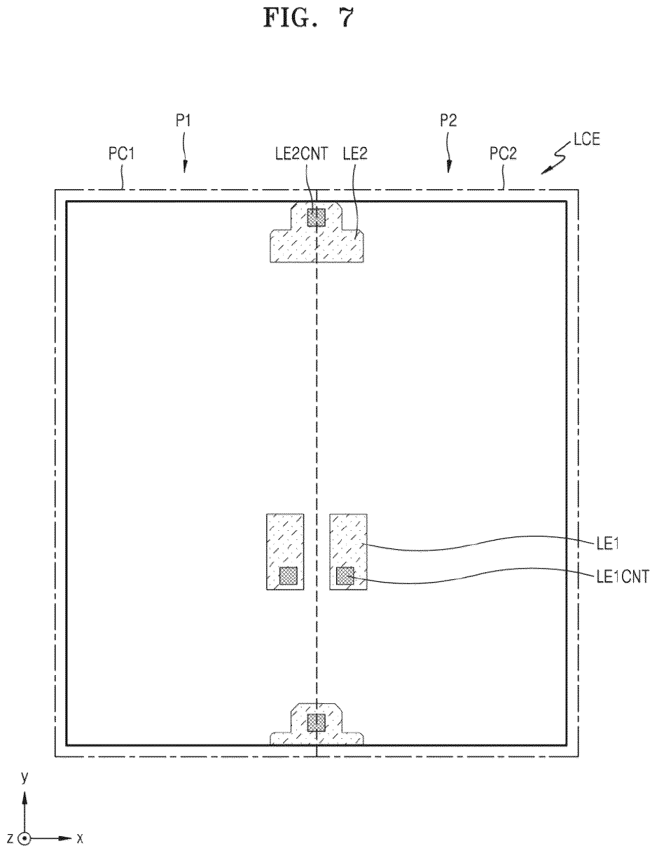

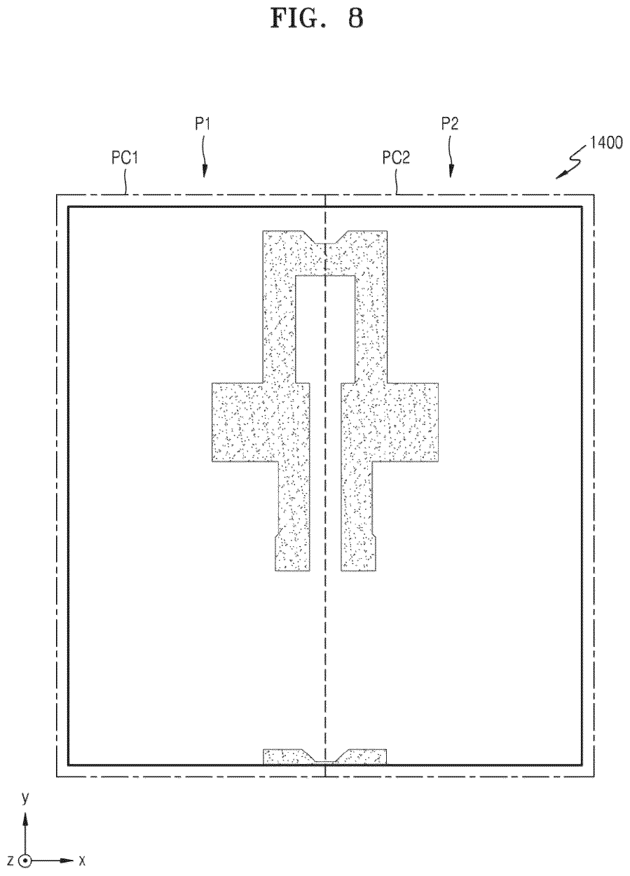

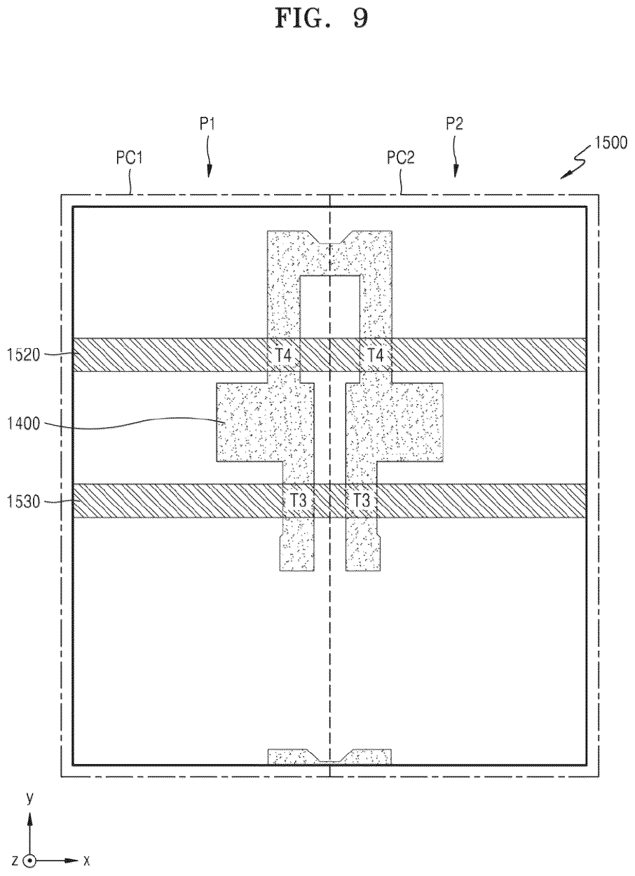

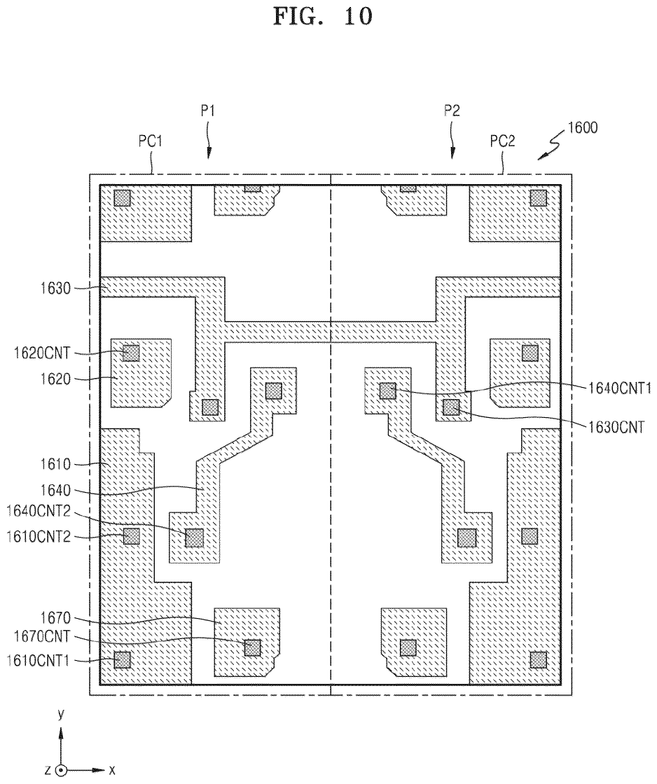

As sequentially shown in FIGS. 4 to 11, in a direction away from the substrate 100, a first semiconductor layer 1100 of FIG. 4, a first gate layer 1200 of FIG. 5, a second gate layer 1300 of FIG. 6, a lower connection electrode layer LCE of FIG. 7, a second semiconductor layer 1400 of FIG. 8, a third gate layer 1500 of FIG. 9, a first connection electrode layer 1600 of FIG. 10, and a second connection electrode layer 1700 of FIG. 11 are arranged. In addition, insulating layers may be arranged between these layers.

For example, as shown in FIG. 4, the first semiconductor layer 1100 may be arranged on the substrate 100. The first semiconductor layer 1100 may include a silicon semiconductor. In some embodiments, the first semiconductor layer 1100 may include amorphous silicon and/or polycrystalline silicon. For example, the first semiconductor layer 1100 may include polycrystalline silicon crystallized at low temperature. In some embodiments, if (e.g., when) needed, ions may be implanted in at least a portion of the first semiconductor layer 1100.

Because the driving transistor T1, the switching transistor T2, the operation control transistor T5, the emission control transistor T6, and the second initialization transistor T7 may be PMOSs as described above, in this case, the thin-film transistors are arranged along the first semiconductor layer 1100 as shown in FIG. 4.

A first gate insulating layer 111 (see FIG. 12) may cover the first semiconductor layer 1100 and be arranged over the substrate 100. The first gate insulating layer 111 may include an insulating material. In some embodiments, the first gate insulating layer 111 may include an inorganic insulating material such as silicon oxide (SiOₓ), silicon nitride (SiNₓ), and/or silicon oxynitride (SiOₓN_{y}), and may have a single-layered or multi-layered structure including the above materials (e.g., a structure having a layer or multiple layers of silicon oxide (SiOₓ), silicon nitride (SiNₓ), and silicon oxynitride (SiOₓN_{y})).

The first gate layer 1200 shown in FIG. 5 may be arranged on the first gate insulating layer 111. For convenience, FIG. 5 shows the first gate layer 1200 together with the first semiconductor layer 1100. The first gate layer 1200 may include a first gate line 1210, a first gate electrode 1220, and a second gate line 1230.

The first gate line 1210 may be extended in a first direction (e.g., an x axis direction). The first gate line 1210 may be the first scan line SL1 or the next scan line SLn of FIG. 2. For example, in the first pixel P1 as shown in FIG. 5, the first gate line 1210 may correspond to the first scan line SL1 of FIG. 2, and in a pixel adjacent to the first pixel P1 in a +y direction (e.g., pixels located in positive values of the y axis direction), the first gate line 1210 may correspond to the next scan line SLn of FIG. 2. Accordingly, the first scan signals Sn and the next scan signals Sn+1 may be applied to the pixels through the first gate line 1210. Portions of the first gate line 1210 overlapping the first semiconductor layer 1100 may be a switching gate electrode of the switching transistor T2 and a second initialization gate electrode of the second initialization transistor T7.

The first gate electrode 1220 may have an isolated shape. The first gate electrode 1220 may be a driving gate electrode of the driving transistor T1. For reference, a portion of the first semiconductor layer 1100 overlapping the first gate electrode 1220 and a neighboring portion may be a driving semiconductor layer.

The second gate line 1230 may be extended in the first direction (e.g., the x axis direction). The second gate line 1230 may correspond to the emission control line EL of FIG. 2. Portions of the second gate line 1230 overlapping the first semiconductor layer 1100 may be an operation control gate electrode of the operation control transistor T5 and an emission control gate electrode of the emission control gate electrode T6. Emission control signals En may be applied to the pixels through the second gate line 1230.

The first gate layer 1200 may include metal, an alloy, a conductive metal oxide, a transparent conductive material, and/or the like. In some embodiments, the first gate layer 1200 may include silver (Ag), an alloy containing silver and molybdenum (Mo), an alloy containing molybdenum and aluminum (Al), an alloy containing aluminum, aluminum nitride (AlN), and tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The first gate layer 1200 may have a multi-layered structure. In some embodiments, the first gate layer 1200 may have a two-layered structure of Mo/Al (e.g., a structure having a layer of Mo and a layer of Al), and/or a three-layered structure of Mo/Al/Mo (e.g., a structure having a layer of Mo, a layer of Al, and another layer of Mo).

The first interlayer insulating layer 112 (see FIG. 12) may cover the first gate layer 1200 and be arranged on the first gate insulating layer 111. The first interlayer insulating layer 112 may include an insulating material substantially identical/similar to the first gate insulating layer 111. In some embodiments, the first interlayer insulating layer 112 may include an inorganic insulating material such as silicon oxide (SiOₓ), silicon nitride (SiNₓ), and/or silicon oxynitride (SiOₓN_{y}), and may have a single-layered or multi-layered structure including the above materials (e.g., a structure having a layer or multiple layers of silicon oxide (SiOₓ), silicon nitride (SiNₓ), and silicon oxynitride (SiOₓN_{y})).

The second gate layer 1300 shown in FIG. 6 may be arranged on the first interlayer insulating layer 112. The second gate layer 1300 may include a third gate line 1310, a fourth gate line 1320, a capacitor upper electrode 1330, and a first initialization voltage line 1340 (e.g., the first initialization voltage line VL1 of FIG. 2).

The third gate line 1310 may be extended in the first direction (e.g., the x axis direction). The third gate line 1310 may correspond to the previous scan line SLp of FIG. 2. If (e.g., when) viewed in a direction (e.g., a z axis direction) normal (e.g., perpendicular) to the substrate 100, the third gate line 1310 may be apart from the first gate line 1210. The previous scan signals Sn-1 may be applied to the pixels through the third gate line 1310. A portion of the third gate line 1310 overlapping the second semiconductor layer 1400 described in more detail later may be a first initialization lower gate electrode of the first initialization transistor T4.

The fourth gate line 1320 may also be extended in the first direction (e.g., the x axis direction). The fourth gate line 1320 may correspond to the second scan line SL2 of FIG. 2. If (e.g., when) viewed in a direction (e.g., the z axis direction) normal (e.g., perpendicular) to the substrate 100, the fourth gate line 1320 may be apart from the first gate line 1210 and the third gate line 1310 (in a plan view). The second scan signals Sn′ may be applied to the pixels through the fourth gate line 1320. A portion of the fourth gate line 1320 overlapping the second semiconductor layer 1400 described in more detail later may be a compensation lower gate electrode of the compensation transistor T3.

The third gate line 1310 and the fourth gate line 1320 may be arranged under the second semiconductor layer 1400 described in more detail later with reference to FIG. 8 to not only serve as gate electrodes but also serve as lower protective metals protecting portions overlapping the third gate line 1310 and the fourth gate line 1320 of the second semiconductor layer 1400.

The capacitor upper electrode 1330 may overlap the first gate electrode 1220 and be extended in the first direction (e.g., the x axis direction). The capacitor upper electrode 1330 may correspond to the second capacitor electrode CE2 and constitute the storage capacitor Cst in cooperation with the first gate electrode 1220. The driving voltage ELVDD may be applied to the capacitor upper electrode 1330. In addition, a hole passing through the capacitor upper electrode 1330 may be formed in the capacitor upper electrode 1330, and at least a portion of the first gate electrode 1220 may overlap the hole.

The first initialization voltage line 1340 corresponding to the first initialization voltage line VL1 of FIG. 2, may be extended in the first direction (e.g., the x axis direction). If (e.g., when) viewed in a direction (e.g., the z axis direction) normal (e.g., perpendicular) to the substrate 100, the first initialization voltage line 1340 may be apart from the third gate line 1310. The first initialization voltage Vint1 may be applied to the pixels through the first initialization voltage line 1340. The first initialization voltage line 1340 may at least partially overlap the second semiconductor layer 1400 described in more detail later and be configured to transfer the first initialization voltage Vint1 to the second semiconductor layer 1400. The first initialization voltage line 1340 may be electrically connected to the second semiconductor layer 1400 through a contact hole LE2CNT described in more detail later with reference to FIG. 7.

The second gate layer 1300 may include metal, an alloy, a conductive metal oxide, a transparent conductive material, and/or the like. In some embodiments, the second gate layer 1300 may include silver (Ag), an alloy containing silver and molybdenum (Mo), an alloy containing molybdenum and aluminum (Al), an alloy containing aluminum, aluminum nitride (AlN), and tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The second gate layer 1300 may have a multi-layered structure. In some embodiments, the second gate layer 1300 may have a two-layered structure of Mo/Al (e.g., a structure having a layer of Mo and a layer of Al), or a three-layered structure of Mo/Al/Mo (e.g., a structure having a layer of Mo, a layer of Al, and another layer of Mo).

The second gate insulating layer 113 (see FIG. 12) may cover the second gate layer 1300 and be arranged on the first interlayer insulating layer 112. The second gate insulating layer 113 may include an insulating material. In some embodiments, the second gate insulating layer 113 may include an inorganic insulating material such as silicon oxide (SiOₓ), silicon nitride (SiNₓ), and/or silicon oxynitride (SiOₓN_{y}), and may have a single-layered or multi-layered structure including the above materials (e.g., a structure having a layer or multiple layers of silicon oxide (SiOₓ), silicon nitride (SiNₓ), and silicon oxynitride (SiOₓN_{y})).

As shown in FIG. 7, the lower connection electrode layer LCE may be arranged on the second gate insulating layer 113. The lower connection electrode layer LCE may include a first lower connection electrode LE1 and a second lower connection electrode LE2.

The first lower connection electrode LE1 may be electrically connected to the first semiconductor layer 1100 of FIG. 4 through a contact hole LE1CNT. In some embodiments, the first lower connection electrode LE1 may be electrically connected to the first semiconductor layer 1100 of FIG. 4 through the contact hole LE1CNT formed in the first gate insulating layer 111, the first interlayer insulating layer 112, and the second gate insulating layer 113. The second lower connection electrode LE2 may be electrically connected to the second gate layer 1300 of FIG. 7 through the contact hole LE2CNT. In some embodiments, the second lower connection electrode LE2 may be electrically connected to the first initialization voltage line 1340 of the second gate layer 1300 through the contact hole LE2CNT formed in the second gate insulating layer 113.

The lower connection electrode layer LCE may include metal, an alloy, a conductive metal oxide, a transparent conductive material, and/or the like. In some embodiments, the lower connection electrode layer LCE may include silver (Ag), an alloy containing silver and molybdenum (Mo), an alloy containing molybdenum and aluminum (Al), an alloy containing aluminum, aluminum nitride (AlN), and tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The lower connection electrode layer LCE may have a multi-layered structure. In some embodiments, the lower connection electrode layer LCE may have a two-layered structure of Ti/Al (e.g., a structure having a layer of Ti and a layer of Al), or a three-layered structure of Ti/Al/Ti (e.g., a structure having a layer of Ti, a layer of Al, and another layer of Ti).

The second semiconductor layer 1400 shown in FIG. 8 may be arranged on the second gate insulating layer 113. For example, a portion of the second semiconductor layer 1400 may be arranged on the second gate insulating layer 113, and another portion of the second semiconductor layer 1400 may be arranged on the lower connection electrode layer LCE. For example, the second semiconductor layer 1400 may cover at least a portion of the lower connection electrode layer LCE.

Accordingly, the lower connection electrode layer LCE may be arranged between the second gate insulating layer 113 and the second semiconductor layer 1400. For example, at least a portion of the lower connection electrode layer LCE may be arranged between the second gate insulating layer 113 and the second semiconductor layer 1400. For example, the lower connection electrode layer LCE may be in direct contact with the second semiconductor layer 1400, and accordingly, the lower connection electrode layer LCE may be electrically connected to the second semiconductor layer 1400.

For example, the first lower connection electrode LE1 and the second lower connection electrode LE2 may be electrically connected to the second semiconductor layer 1400. For example, the first lower connection electrode LE1 may electrically connect the second semiconductor layer 1400 to the first semiconductor layer 1100. For example, the first lower connection electrode LE1 may electrically connect the compensation transistor T3 and the driving transistor T1 to each other. The second lower connection electrode LE2 may electrically connect the second semiconductor layer 1400 to the first initialization voltage line 1340. Through this, the second lower connection electrode LE2 may be configured to transfer the first initialization voltage Vint1 from the first initialization voltage line 1340 to the first initialization transistor T4.

As described above, the second semiconductor layer 1400 may include an oxide semiconductor. The second semiconductor layer 1400 may be arranged on a layer different from a layer on which the first semiconductor layer 1100 is arranged. When viewed in a direction (e.g., the z axis direction) normal (e.g., perpendicular) to the substrate 100 (in a plan view), the second semiconductor layer 1400 may not overlap the first semiconductor layer 1100.

The third gate insulating layer 114 (see FIG. 12) may cover the second semiconductor layer 1400 and be arranged on the second gate insulating layer 113. For example, the third gate insulating layer 114 may cover the second semiconductor layer 1400 and the lower connection electrode layer LCE and be arranged on the second gate insulating layer 113. For example, if (e.g., when) viewed in a direction (e.g., the z axis direction) normal (e.g., perpendicular) to the substrate 100, at least a portion of the lower connection electrode layer LCE may overlap the second semiconductor layer 1400. The third gate insulating layer 114 may include an insulating material. In some embodiments, the third gate insulating layer 114 may include an inorganic insulating material such as silicon oxide (SiOₓ), silicon nitride (SiNₓ), and/or silicon oxynitride (SiOₓN_{y}), and may have a single-layered or multi-layered structure including the above materials (e.g., a structure having a layer or multiple layers of silicon oxide (SiOₓ), silicon nitride (SiNₓ), and silicon oxynitride (SiOₓN_{y})).

The third gate layer 1500 shown in FIG. 9 may be arranged on the third gate insulating layer 114. The third gate layer 1500 may include a fifth gate line 1520 and a sixth gate line 1530.

The fifth gate line 1520 may be extended in the first direction (e.g., the x axis direction). When viewed in a direction (e.g., the z axis direction) normal (e.g., perpendicular) to the substrate 100, the fifth gate line 1520 may overlap the third gate line 1310. A portion of the fifth gate line 1520 overlapping the second semiconductor layer 1400 may be a first initialization upper gate electrode of the first initialization transistor T4. A portion of the second semiconductor layer 1400 overlapping the fifth gate line 1520 and a neighboring portion thereof may be a first initialization semiconductor layer. The fifth gate line 1520 may be electrically connected to the third gate line 1310. In some embodiments, the fifth gate line 1520 may be electrically connected to the third gate line 1310 through a contact hole formed in an insulating layer between the fifth gate line 1520 and the third gate line 1310. The contact hole may be located inside the display area DA or located in the peripheral area PA. Accordingly, the fifth gate line 1520 and the third gate line 1310 may correspond to the previous scan line SLp of FIG. 2. Accordingly, the previous scan signal Sn−1 may be applied to the pixels through the fifth gate line 1520 and/or the third gate line 1310.

The sixth gate line 1530 may be extended in the first direction (e.g., the x axis direction). If (e.g., when) viewed in a direction (e.g., the z axis direction) normal (e.g., perpendicular) to the substrate 100, the sixth gate line 1530 may overlap the fourth gate line 1320. A portion of the sixth gate line 1530 overlapping the second semiconductor layer 1400 may be a compensation upper gate electrode of the compensation transistor T3. The sixth gate line 1530 may be electrically connected to the fourth gate line 1320. In some embodiments, the sixth gate line 1530 may be electrically connected to the fourth gate line 1320 through a contact hole formed in an insulating layer between the sixth gate line 1530 and the fourth gate line 1320. The contact hole may be located inside the display area Da and/or located in the peripheral area PA. Accordingly, the sixth gate line 1530 and the fourth gate line 1320 may correspond to the second scan line SL2 of FIG. 2. Accordingly, the second scan signal Sn′ may be applied to the pixels through the sixth gate line 1530 and/or the fourth gate line 1320.

The third gate layer 1500 may include metal, an alloy, a conductive metal oxide, a transparent conductive material, and/or the like. In some embodiments, the third gate layer 1500 may include silver (Ag), an alloy containing silver and molybdenum (Mo), an alloy containing molybdenum and aluminum (Al), an alloy containing aluminum, aluminum nitride (AlN), and tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The third gate layer 1500 may have a multi-layered structure. In some embodiments, the third gate layer 1500 may have a two-layered structure of Mo/Al (e.g., a structure having a layer of Mo and a layer of Al), or a three-layered structure of Mo/Al/Mo (e.g., a structure having a layer of Mo, a layer of Al, and another layer of Mo).

The second interlayer insulating layer 115 (see FIG. 12) may cover at least a portion of the third gate layer 1500 of FIG. 9. The second interlayer insulating layer 115 may include an insulating material. In some embodiments, the second interlayer insulating layer 115 may include an inorganic insulating material such as silicon oxide (SiOₓ), silicon nitride (SiNₓ), and/or silicon oxynitride (SiOₓN_{y}), and may have a single-layered or multi-layered structure including the above materials (e.g., a structure having a layer or multiple layers of silicon oxide (SiOₓ), silicon nitride (SiNₓ), and silicon oxynitride (SiOₓN_{y})).

The first connection electrode layer 1600 shown in FIG. 10 may be arranged on the second interlayer insulating layer 115. The first connection electrode 1600 may include a first connection electrode 1620, a second connection electrode 1610, a second initialization voltage line 1630, a third connection electrode 1670, and a fourth connection electrode 1640.

The first connection electrode 1620 may be electrically connected to the first semiconductor layer 1100 through a contact hole 1620CNT. In some embodiments, the first connection electrode 1620 may be electrically connected to the first semiconductor layer 1100 through the contact hole 1620CNT formed in the first gate insulating layer 111, the first interlayer insulating layer 112, the second gate insulating layer 113, the third gate insulating layer 114, and the second interlayer insulating layer 115. A data signal Dm from the data line 1710 described in more detail later with reference to FIG. 11 may be transferred to the first semiconductor layer 1100 through the first connection electrode 1620 and applied to the switching transistor T2.

The second initialization voltage line 1630 may be extended in the first direction (e.g., the x axis direction). The second initialization voltage line 1630 corresponding to the second initialization voltage line VL2 of FIG. 2 may be configured to apply the second initialization voltage Vint2 to the pixels. Because the second initialization voltage line 1630 is electrically connected to the first semiconductor layer 1100 through a contact hole 1630CNT, the second initialization voltage Vint2 may be transferred to the first semiconductor layer 1100 and applied to the second initialization transistor T7.

The second connection electrode 1610 may be electrically connected to the first semiconductor layer 1100 through a contact hole 1610CNT1. In some embodiments, the second connection electrode 1610 may be electrically connected to the first semiconductor layer 1100 through the contact hole 1610CNT1 formed in the first gate insulating layer 111, the first interlayer insulating layer 112, the second gate insulating layer 113, the third gate insulating layer 114, and the second interlayer insulating layer 115. The driving voltage ELVDD from the driving voltage line 1730 described in more detail later with reference to FIG. 11 may be transferred to the first semiconductor layer 1100 through the second connection electrode 1610 and applied to the operation control transistor T5. The second connection electrode 1610 electrically connected to the capacitor upper electrode 1330 (e.g., the second capacitor electrode CE2 of FIG. 2) through a contact hole 1610CNT2, which is an additional contact hole, may be configured to transfer the driving voltage ELVDD to the capacitor upper electrode 1330.

The third connection electrode 1670 may be electrically connected to the first semiconductor layer 1100 through a contact hole 1670CNT. The third connection electrode 1670 may be configured to transfer a driving current from the first semiconductor layer 1100 or the second initialization voltage Vint2 to the organic light-emitting diode OLED.

The fourth connection electrode 1640 may be electrically connected to the second semiconductor layer 1400 through a contact hole 1640CNT1 formed in one side thereof. In addition, the fourth connection electrode 1640 may be electrically connected to the first gate electrode 1220, which is a driving gate electrode, through a contact hole 1640CNT2 formed on another side thereof and passing through an opening 1330-OP of the capacitor upper electrode 1330. Accordingly, the fourth connection electrode 1640 may electrically connect the first initialization semiconductor layer, which is a portion of the second semiconductor layer 1400, to the driving gate electrode. The first initialization voltage Vint1 may be transferred to the first gate electrode 1220, which is the driving gate electrode, through the second semiconductor layer 1400 and the fourth connection electrode 1640.

The first connection electrode layer 1600 may include metal, an alloy, a conductive metal oxide, a transparent conductive material, and/or the like. In some embodiments, the first connection electrode layer 1600 may include silver (Ag), an alloy containing silver, molybdenum (Mo), an alloy containing molybdenum, aluminum (Al), an alloy containing aluminum, aluminum nitride (AlN), and tungsten (W) , tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The first connection electrode layer 1600 may have a multi-layered structure. In some embodiments, the first connection electrode layer 1600 may have a two-layered structure of Ti/Al (e.g., a structure having a layer of Ti and a layer of Al), or a three-layered structure of Ti/Al/Ti (e.g., a structure having a layer of Ti, a layer of Al, and another layer of Ti).

A first planarization layer 116 may cover the first connection electrode layer 1600 and be arranged on the sixth interlayer insulating layer 115. The first planarization layer 116 may include an organic insulating material. In some embodiments, the first planarization layer 116 may include benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a (e.g., any suitable) mixture (combination) thereof.

The second connection electrode layer 1700 shown in FIG. 11 may be arranged on the first planarization layer 116. The second connection electrode layer 1700 may include the data line 1710, the driving voltage line 1730, and an upper connection electrode 1740.

The data line 1710 may be extended in the second direction (e.g., the y axis direction). The data line 1710 may correspond to the data line DL of FIG. 2. Because the data line 1710 is electrically connected to the first connection electrode 1620 through a contact hole 1710CNT, a data signal Dm from the data line 1710 may be transferred to the first semiconductor layer 1100 through the first connection electrode 1620 and applied to the switching transistor T2.

The driving voltage line 1730 may be extended approximately in the second direction (e.g., the y axis direction). The driving voltage line 1730 may correspond to the driving voltage line PL of FIG. 2. The driving voltage line 1730 may be configured to apply the driving voltage ELVDD to the pixels. Because the driving voltage line 1730 is electrically connected to the second connection electrode 1610 through a contact hole 1730CNT, the driving voltage ELVDD may be transferred to the operation control transistor T5 and the capacitor upper electrode 1330 as described above. The driving voltage line 1730 of the first pixel circuit PC1 may be integrated with the driving voltage line 1730 of the second pixel circuit PC2 adjacent thereto. In other words, the driving voltage line 1730 may be extended to be in both of the first pixel circuit PC1 and the second pixel circuit PC2 as a whole. For example, the driving voltage line 1730 may extend in the y-axis direction and correspond to the driving voltage line PL in FIG. 2. It applies the driving voltage ELVDD to the pixels and is electrically connected to the second connection electrode 1610 through a contact hole 1730CNT. This connection allows the driving voltage ELVDD to be transferred to the operation control transistor T5 and the capacitor upper electrode 1330. Additionally, the driving voltage line 1730 of the first pixel circuit PC1 may be integrated with that of the adjacent second pixel circuit PC2, extending across both circuits PC1 and PC2.

The upper connection electrode 1740 may be electrically connected to the third connection electrode 1670 through a contact hole 1740CNT1. The upper connection electrode 1740 is connected to a pixel electrode 210 (see FIG. 12) in the above through a contact hole 1740CNT2 formed in an insulating layer arranged on. Accordingly, the driving current or the second initialization voltage Vint2 from the first semiconductor layer 1100 may be transferred to the first electrode (the pixel electrode) of the organic light-emitting diode OLED through the third connection electrode 1670 and the upper connection electrode 1740.

The second connection electrode layer 1700 may include metal, an alloy, a conductive metal oxide, a transparent conductive material and/or the like. In some embodiments, the second connection electrode layer 1700 may include silver (Ag), an alloy containing silver and molybdenum (Mo), an alloy containing molybdenum and aluminum (Al), an alloy containing aluminum, aluminum nitride (AlN), and tungsten (W), tungsten nitride (WN), copper (Cu), nickel (Ni), chromium (Cr), chromium nitride (CrN), titanium (Ti), tantalum (Ta), platinum (Pt), scandium (Sc), indium tin oxide (ITO), indium zinc oxide (IZO), and/or the like. The second connection electrode layer 1700 may have a multi-layered structure. In some embodiments, the second connection electrode layer 1700 may have a two-layered structure of Ti/Al (e.g., a structure having a layer of Ti and a layer of Al), or a three-layered structure of Ti/Al/Ti (e.g., a structure having a layer of Ti, a layer of Al, and another layer of Ti).

The second planarization layer 119 (see FIG. 12) may cover the second connection electrode layer 1700 and be arranged on the first planarization layer 116. The second planarization layer 117 may include an organic insulating layer. In some embodiments, the second planarization layer 117 may include benzocyclobutene (BCB), polyimide, hexamethyldisiloxane (HMDSO), polymethylmethacrylate (PMMA), polystyrene, polymer derivatives having a phenol-based group, an acryl-based polymer, an imide-based polymer, an aryl ether-based polymer, an amide-based polymer, a fluorine-based polymer, a p-xylene-based polymer, a vinyl alcohol-based polymer, and/or a (e.g., any suitable) mixture thereof.

The organic light-emitting diode OLED may be arranged on the second planarization layer 117. The organic light-emitting diode OLED may include the pixel electrode 210, an intermediate layer 220, and the opposite electrode 230, where the intermediate layer 220 includes an emission layer.

The pixel electrode 210 may be a (semi) light-transmissive electrode or a reflective electrode. In some embodiments, the pixel electrode 210 may include a reflective layer and a transparent or semi-transparent electrode layer on the reflective layer, where the reflective layer includes sliver (Ag), magnesium (Mg), aluminum (Al), platinum (Pt), palladium (Pd), gold (Au), nickel (Ni), neodymium (Nd), iridium (Ir), chromium (Cr), and/or a compound thereof. The transparent or semi-transparent electrode layer may include at least one of indium tin oxide (ITO), indium zinc oxide (IZO), zinc oxide (ZnO), indium oxide (InₓO_{y}, e.g., In₂O₃), indium gallium oxide (IGO), and/or aluminum zinc oxide (AZO). In some embodiments, the pixel electrode 210 may have a three-layered structure of ITO/Ag/ITO (e.g., a structure having a layer of ITO, a layer of Ag, and another layer of ITO).

In one or more embodiments, a pixel-defining layer may be arranged on the second planarization layer 117. The pixel-defining layer may prevent or reduce arcs and/or the like from occurring at the edges of each pixel electrode 210 by increasing a distance between the edges of each pixel electrode 210 and the opposite electrode 230 over the pixel electrode 210. The pixel-defining layer may include an organic insulating material, such as polyimide, an acrylic resin, benzocyclobutene, a phenolic resin, and/or the like. The pixel-defining layer may be formed by utilizing spin coating and/or the like.

At least a portion of the intermediate layer 220 of the organic light-emitting diode OLED may be arranged in an opening formed in the pixel-defining layer. An emission area of an organic light-emitting diode OLED may be defined by the opening.

The intermediate layer 220 may include the emission layer. The emission layer may include an organic material including a fluorescent and/or phosphorous material configured to emit red, green, blue, and/or white light. The emission layer may include a polymer organic material and/or a low molecular weight organic material. Functional layers may be selectively further arranged under and/or on the emission layer, the functional layers including a hole transport layer (HTL), a hole injection layer (HIL), an electron transport layer (ETL), and/or an electron injection layer (EIL).

The emission layer may have a shape patterned to correspond to each of the pixel electrodes 210. Layers of the intermediate layer 220 other than the emission layer may be integrated over the plurality of pixel electrodes 210. However, one or mor e suitable modifications may be made.

The opposite electrode 230 may be a light-transmissive electrode or a reflective electrode. In some embodiments, the opposite electrode 230 may be a transparent or semi-transparent electrode and may include a metal thin film including lithium (Li), calcium (Ca), lithium fluoride (LiF), aluminum (Al), silver (Ag), magnesium (Mg), and/or a compound thereof and having a small work function. In addition, the opposite electrode 230 may further include a transparent conductive oxide (TCO) layer, such as indium tin oxide (ITO), indium zinc oxide (IZO), zinc oxide (ZnO), or indium oxide (InₓO_{y}, e.g., In₂O₃) arranged on the metal thin film. The opposite electrode 230 may be formed as one body over the entire surface of the display area DA and arranged on the intermediate layer 220 and the pixel-defining layer.

In the display apparatus 1 according to one or more embodiments, the second semiconductor layer 1400 may be electrically connected to layers (e.g., the first semiconductor layer 1100, the first initialization voltage line 1340) arranged below the second semiconductor layer 1400 by a connection electrode of the lower connection electrode layer LCE. In addition, the second semiconductor layer 1400 may be electrically connected to a layer (e.g., the first gate electrode 1220) arranged below the second semiconductor layer 1400 by a connection electrode (for example, a bridge electrode) of the first connection electrode layer 1600.

For example, as shown in FIG. 12, the second semiconductor layer 1400 may be electrically connected to the first semiconductor layer 1100 through the first lower connection electrode LE1. For example, the first lower connection electrode LE1 may be electrically connected to the second semiconductor layer 1400 and the first semiconductor layer 1100. The first lower connection electrode LE1 may be in contact with the first semiconductor layer 1100 through the contact hole LE1CNT formed in the first gate insulating layer 111, the second gate insulating layer 113, and the first interlayer insulating layer 112. Accordingly, the first lower connection electrode LE1 may be electrically connected to the first semiconductor layer 1100. The first lower connection electrode LE1 may be in direct contact with the second semiconductor layer 1400. For example, because the second semiconductor layer 1400 covers at least a portion of the lower connection electrode layer, for example, at least a portion of the first lower connection electrode layer LE1, the first lower connection electrode layer LE1 may be electrically connected to the second semiconductor layer 1400.

Similarly, as shown in FIG. 13, the second semiconductor layer 1400 may be electrically connected to the second gate layer 1300 through the second lower connection electrode LE2. For example, the second lower connection electrode LE2 may be electrically connected to the second semiconductor layer 1400 and the second gate layer 1300. The second lower connection electrode LE2 may be in contact with the first initialization voltage line 1340 of the second gate layer 1300 through the contact hole LE2CNT formed in the second gate insulating layer 113. Accordingly, the second lower connection electrode LE2 may be electrically connected to the second gate layer 1300. The second lower connection electrode LE2 may be in direct contact with the second semiconductor layer 1400. For example, because the second semiconductor layer 1400 covers at least a portion of the lower connection electrode layer, for example, at least a portion of the second lower connection electrode layer LE2, the second lower connection electrode layer LE2 may be electrically connected to the second semiconductor layer 1400.

Although it is shown in FIG. 12 that the second semiconductor layer 1400 covers a portion of the first lower connection electrode LE1 and it is shown in FIG. 13 that the second semiconductor layer 1400 covers a portion of the second lower connection electrode LE2, the disclosure is not limited thereto. In some embodiments, the second semiconductor layer 1400 may cover the first lower connection electrode LE1 entirely, and the second semiconductor layer 1400 may cover the second lower connection electrode LE2 entirely.

As shown in FIG. 14, the second semiconductor layer 1400 may be electrically connected to the first gate layer 1200 through a connection electrode of the first connection electrode layer 1600. For example, the connection electrode of the first connection electrode layer 1600 may be electrically connected to the second semiconductor layer 1400 and the first gate layer 1200. For example, the fourth connection electrode 1640 of the second semiconductor layer 1400 may be in contact with the second semiconductor layer 1400 through the contact hole 1640CNT1 formed in the third gate insulating layer 114 and the second interlayer insulating layer 115. Accordingly, the fourth connection electrode 1640 may be electrically connected to the second semiconductor layer 1400. The fourth connection electrode 1640 may be in contact with the first gate electrode 1220 of the first gate layer 1200 through the contact hole 1640CNT2 formed in the first interlayer insulating layer 112, the second gate insulating layer 113, the third gate insulating layer 114, and the second interlayer insulating layer 115. Accordingly, the fourth connection electrode 1640 may be electrically connected to the first gate layer 1200.

For example, in the display apparatus 1 according to one or more embodiments, because the second semiconductor layer 1400 is electrically connected to the layers (e.g., the first semiconductor layer 1100, the first initialization voltage line 1340) arranged below the second semiconductor layer 1400 by the connection electrode of the lower connection electrode layer LCE, the number of the connection electrodes of the first connection electrode layer 1600 may be reduced. In other words, the number of bridge electrodes that connect the semiconductor layer to the wirings may be reduced, therefore, additional space may be freed up for other utilizations. Accordingly, a space may be efficiently utilized, and the design freedom of the display apparatus may increase. That is, in the display apparatus 1, the second semiconductor layer 1400 is electrically connected to the layers (such as the first semiconductor layer 1100 and the first initialization voltage line 1340) located below it via the connection electrode of the lower connection electrode layer LCE. This reduces the number of connection electrodes in the first connection electrode layer 1600. Consequently, the number of bridge electrodes needed to connect the semiconductor layer to the wirings is minimized, freeing up additional space for other uses. This efficient space utilization enhances the design flexibility of the display apparatus.

Although it is shown in FIGS. 3 to 14 that the lower connection electrode layer LCE includes both (e.g., simultaneously) the first lower connection electrode LE1 and the second lower connection electrode LE2, the disclosure is not limited thereto, and the lower connection electrode layer LCE may include only the first lower connection electrode LE1 or include only the second lower connection electrode LE2. For example, the lower connection electrode layer LCE may include at least one of the first lower connection electrode LE1 and the second lower connection electrode LE2. Even in this case, because the second semiconductor layer 1400 is electrically connected to the layers (e.g., the first semiconductor layer 1100, the first initialization voltage line 1340) arranged below the second semiconductor layer 1400 by the connection electrode of the lower connection electrode layer LCE, the number of the connection electrodes of the first connection electrode layer 1600 may be reduced. Accordingly, a space may be efficiently utilized, and the design freedom of the display apparatus may increase. In other words, although FIGS. 3 to 14 show that the lower connection electrode layer LCE includes both the first lower connection electrode LE1 and the second lower connection electrode LE2, it is not limited to this configuration. The LCE may include either LE1 or LE2, or both. Regardless of the configuration, the second semiconductor layer 1400 is electrically connected to the layers (such as the first semiconductor layer 1100 and the first initialization voltage line 1340) below it via the LCE. This reduces the number of connection electrodes in the first connection electrode layer 1600, leading to efficient space utilization and increased design flexibility for the display apparatus.

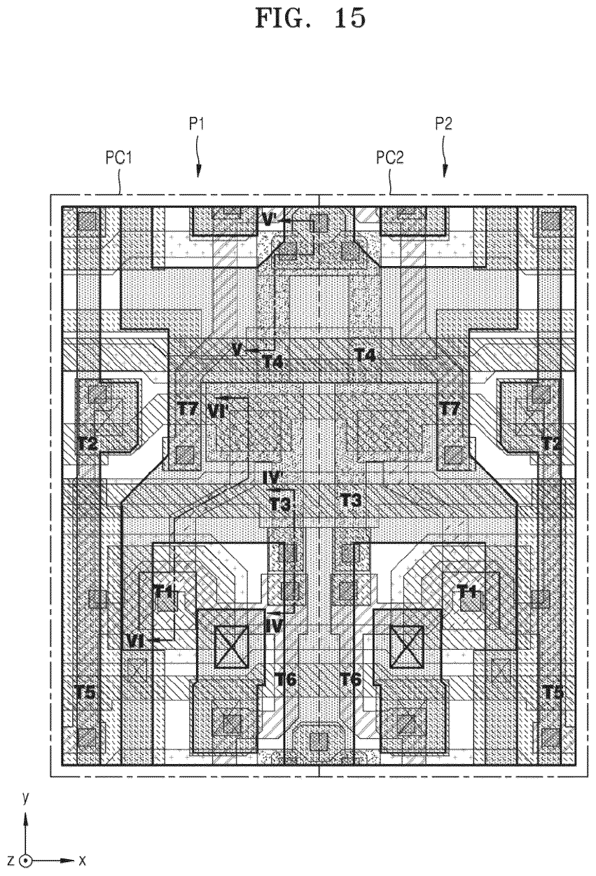

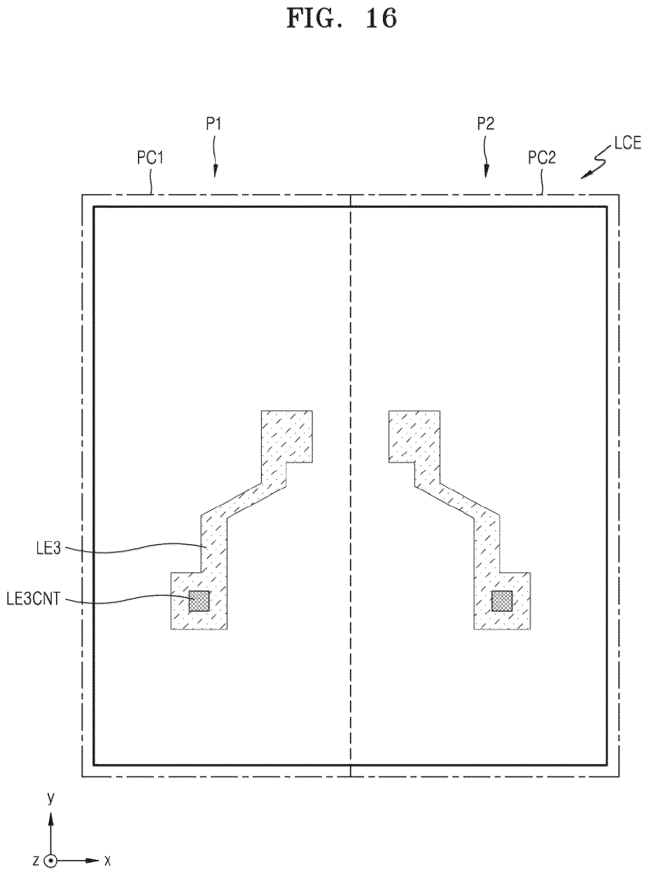

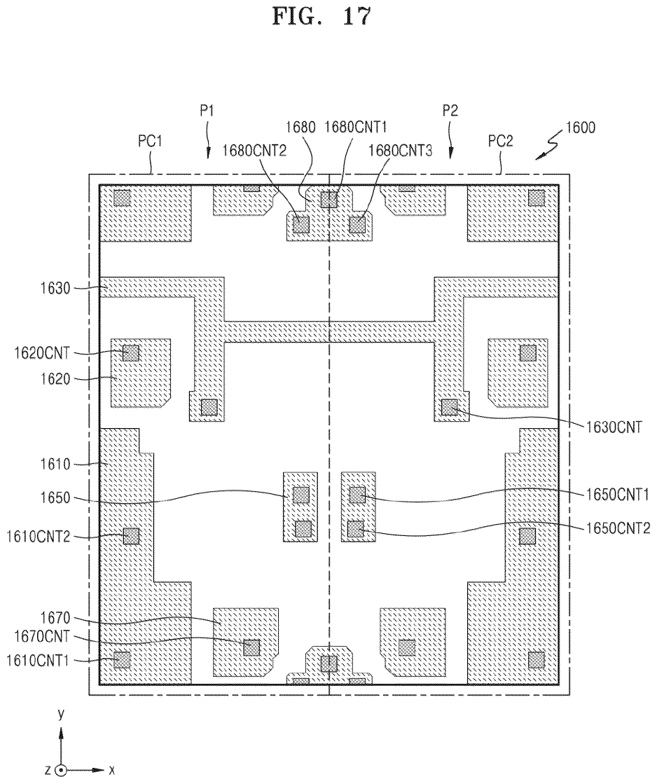

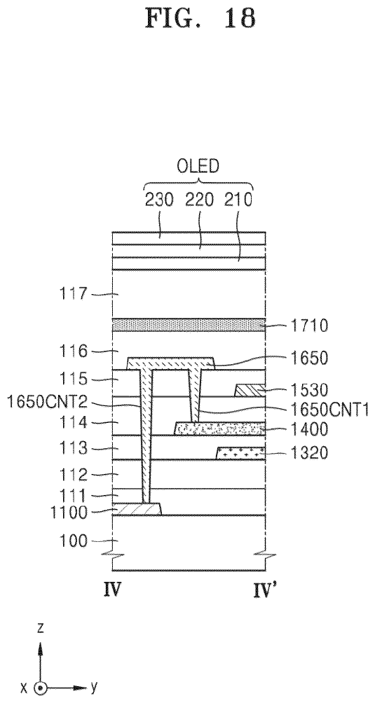

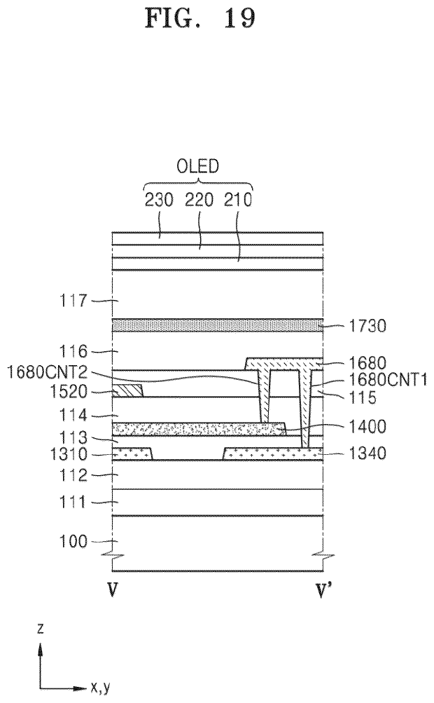

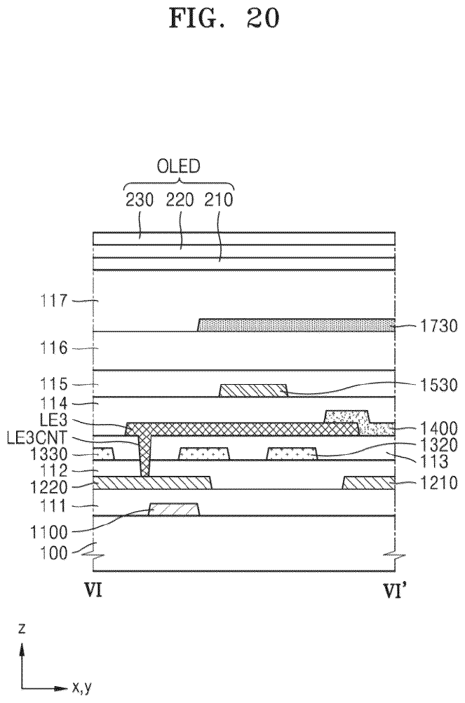

FIG. 15 is a schematic layout view showing the positions of transistors T1, T2, T3, T4, T5, T6, T7, the storage capacitor Cst, and/or the like in the pixels of the display apparatus 1 according to one or more embodiments. FIGS. 16 and 17 are portions of schematic layout views of elements such as transistors T1, T2, T3, T4, T5, T6, T7, the storage capacitor Cst, for each layer, of a display apparatus shown in FIG. 15. FIG. 18 is a schematic cross-sectional view of display apparatus 1 of FIG. 15, taken along the line IV-IV′ of FIG. 15. FIG. 19 is a schematic cross-sectional view of the display apparatus 1 of FIG. 15, taken along the line V-V′ of FIG. 15. FIG. 20 is a schematic cross-sectional view of the display apparatus 1 of FIG. 15, taken along the line VI-VI′ of FIG. 15.

Because the display apparatus 1 according to one or more embodiments is similar to the display apparatus 1 described above with reference to FIGS. 1 to 14, differences from the display apparatus 1 described with reference to FIGS. 1 to 14 are mainly described in more detail. In FIGS. 15 to 20, the same reference numerals as those of FIGS. 1 to 14 denote the same members, and thus, repeated descriptions thereof are omitted.

The display apparatus 1 according to one or more embodiments described with reference to FIGS. 1 to 15 may include the first semiconductor layer 1100, the first gate layer 1200, the second gate layer 1300, the lower connection electrode layer LCE, the second semiconductor layer 1400, the third gate layer 1500, the first connection electrode layer 1600, and the second connection electrode layer 1700. Also, the display apparatus 1 according to the present embodiment may include the first semiconductor layer 1100, the first gate layer 1200, the second gate layer 1300, the lower connection electrode layer LCE, the second semiconductor layer 1400, the third gate layer 1500, the first connection electrode layer 1600, and the second connection electrode layer 1700.

However, in the display apparatus 1 according to the present embodiment, in a direction away from the substrate 100, a first semiconductor layer 1100 of FIG. 4, a first gate layer 1200 of FIG. 5, a second gate layer 1300 of FIG. 6, a lower connection electrode layer LCE of FIG. 16, a second semiconductor layer 1400 of FIG. 8, a third gate layer 1500 of FIG. 9, a first connection electrode layer 1600 of FIG. 17, and a second connection electrode layer 1700 of FIG. 11 are arranged. In addition, insulating layers may be arranged between these layers.

As shown in FIG. 16, the lower connection electrode layer LCE of the display apparatus 1 according to the present embodiment does not include the first lower connection electrode LE1 and the second lower connection electrode LE2 and may include a third lower connection electrode LE3. The third lower connection electrode LE3 may be electrically connected to the first gate layer 1200 of FIG. 5 through a contact hole LE3CNT. In some embodiments, the third lower connection electrode LE3 may be electrically connected to the first gate electrode 1220 of the first gate layer 1200 through the contact hole LE3CNT formed in the first interlayer insulating layer 112 and the second interlayer insulating layer 113.

Even in this case, a portion of the second semiconductor layer 1400 may be arranged on the second gate insulating layer 113, and another portion of the second semiconductor layer 1400 may be arranged on the lower connection electrode layer LCE. For example, the second semiconductor layer 1400 may cover at least a portion of the lower connection electrode layer LCE. Accordingly, the lower connection electrode layer LCE may be arranged between the second gate insulating layer 113 and the second semiconductor layer 1400. For example, the lower connection electrode layer LCE may be in direct contact with the second semiconductor layer 1400, and accordingly, the lower connection electrode layer LCE may be electrically connected to the second semiconductor layer 1400. For example, the third lower connection electrode LE3 may be electrically connected to the second semiconductor layer 1400. For example, the third lower connection electrode LE3 may electrically connect the second semiconductor layer 1400 to the first gate layer 1200. Accordingly, the third lower connection electrode LE3 may electrically connect the first initialization semiconductor layer, which is a portion of the second semiconductor layer 1400, to the driving gate electrode. The first initialization voltage Vint1 may be transferred to the first gate electrode 1220, which is the driving gate electrode, through the second semiconductor layer 1400 and the third lower connection electrode LE3. The third gate insulating layer may cover the second semiconductor layer 1400 and the lower connection electrode layer LCE.

As shown in FIG. 17, the first connection electrode layer 1600 of the display apparatus 1 according to the present embodiment does not include the fourth connection electrode 1640 and may include a fifth connection electrode 1650 and a sixth connection electrode 1680.

The fifth connection electrode 1650 may electrically connect the second semiconductor layer 1400 and the first semiconductor layer 1100 to each other through contact holes 1650CNT1 and 1650CNT2 formed in one side and another side thereof. For example, the fifth connection electrode 1650 may electrically connect the compensation transistor T3 and the driving transistor T1 to each other.

The sixth connection electrode 1680 may be electrically connected to the second semiconductor layer 1400 through contact holes 1680CNT2 and 1680CNT3. In addition, the sixth connection electrode 1680 may be electrically connected to the first initialization voltage line 1340 of FIG. 7 through a contact hole 1680CNT1. Through this, the sixth connection electrode 1680 may be configured to transfer the first initialization voltage Vint1 from the first initialization voltage line 1340 to the first initialization transistor T4.

Like the display apparatus 1 according to one or more embodiments described with reference to FIGS. 1 to 15, even in the display apparatus 1 according to the present embodiment, the second semiconductor layer 1400 may be electrically connected to the layer (e.g., the first gate electrode 1220) arranged below the second semiconductor layer 1400 by the connection electrode of the lower connection electrode layer LCE. In addition, the second semiconductor layer 1400 may be electrically connected to layers (e.g., the first semiconductor layer 1100, the first initialization voltage line 1340) arranged below the second semiconductor layer 1400 by a connection electrode (for example, a bridge electrode) of the first connection electrode layer 1600.

For example, as shown in FIG. 18, the second semiconductor layer 1400 may be electrically connected to the first semiconductor layer 1100 through the fifth connection electrode 1650. For example, the fifth connection electrode 1650 may be electrically connected to the second semiconductor layer 1400 and the first semiconductor layer 1100. The fifth connection electrode 1650 may be in contact with the second semiconductor layer 1400 through the contact hole 1650CNT1 formed in the third gate insulating layer 114 and the second interlayer insulating layer 115. Accordingly, the fifth connection electrode 1650 may be electrically connected to the second semiconductor layer 1400. The fifth connection electrode 1650 may be in contact with the first semiconductor layer 1100 through the contact hole 1650CNT2 formed in the first gate insulating layer 111, the first interlayer insulating layer 112, the second gate insulating layer 113, the third gate insulating layer 114, and the second interlayer insulating layer 115. Accordingly, the fifth connection electrode 1650 may be electrically connected to the first semiconductor layer 1100.

Similarly, as shown in FIG. 19, the second semiconductor layer 1400 may be electrically connected to the second gate layer 1300 through the sixth connection electrode 1680. For example, the sixth lower connection electrode 1680 may be electrically connected to the second semiconductor layer 1400 and the second gate layer 1300. The sixth connection electrode 1680 may be in contact with the second semiconductor layer 1400 through the contact hole 1680CNT2 formed in the third gate insulating layer 114 and the second interlayer insulating layer 115. Accordingly, the sixth connection electrode 1680 may be electrically connected to the second semiconductor layer 1400. The sixth connection electrode 1680 may be in contact with the first initialization voltage line 1340 of the second gate layer 1300 through the contact hole 1680CNT1 formed in the second gate insulating layer 113, the third gate insulating layer 114, and the second interlayer insulating layer 115. Accordingly, the fifth connection electrode 1650 may be electrically connected to the second gate layer 1300.

As shown in FIG. 20, the second semiconductor layer 1400 may be electrically connected to the first gate layer 1200 through the third lower connection electrode LE3. For example, the third lower connection electrode LE3 may be electrically connected to the second semiconductor layer 1400 and the first gate layer 1200. The third lower connection electrode LE3 may be in contact with the first gate electrode 1220 of the first gate layer 1200 through the contact hole LE3CNT formed in the first interlayer insulating layer 112 and the second interlayer insulating layer 113. Accordingly, the third lower connection electrode LE3 may be electrically connected to the first gate layer 1200. The third lower connection electrode LE3 may be in direct contact with the second semiconductor layer 1400. For example, because the second semiconductor layer 1400 covers at least a portion of the lower connection electrode layer, for example, at least a portion of the third lower connection electrode layer LE3, the third lower connection electrode layer LE3 may be electrically connected to the second semiconductor layer 1400.

Although it is shown in FIG. 20 that the second semiconductor layer 1400 covers a portion of the third lower connection electrode LE3, the disclosure is not limited thereto. In some embodiments, the second semiconductor layer 1400 may cover the third lower connection electrode LE3 entirely.

For example, like the display apparatus 1 according to one or more embodiments described with reference to FIGS. 1 to 15, even in the display apparatus 1 according to the present embodiment, because the second semiconductor layer 1400 is electrically connected to the layer (e.g., the first gate electrode 1220) arranged below the second semiconductor layer 1400 by the connection electrode of the lower connection electrode layer LCE, the number of the connection electrodes of the first connection electrode layer 1600 may be reduced. Accordingly, a space may be efficiently utilized, and the design freedom of the display apparatus may increase. In other words, similar to the display apparatus 1 described in the embodiments referenced in FIGS. 1 to 15, the present embodiment also features the second semiconductor layer 1400 electrically connected to the layer (e.g., the first gate electrode 1220) arranged below it via the connection electrode of the lower connection electrode layer LCE. That is, this configuration reduces the number of connection electrodes in the first connection electrode layer 1600, efficiently utilizing space and enhancing the design flexibility of the display apparatus.

According to one or more embodiments, a display apparatus in which a space may be efficiently utilized may be implemented. However, the scope of the disclosure is not limited by this effect.

As used herein, the terms “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is also inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

In the context of the present disclosure and unless otherwise defined, the terms “use,” “using,” and “used” may be considered synonymous with the terms “utilize,” “utilizing,” and “utilized,” respectively.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display apparatus, a device of manufacturing a display apparatus, and/or any other relevant devices or components according to embodiments of the present disclosure described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

It should be understood that embodiments described herein should be considered in a descriptive sense only and not for purposes of limitation. Descriptions of features or aspects within each embodiment should typically be considered as available for other similar features or aspects in one or more embodiments. While one or more embodiments have been described with reference to the drawings, it will be understood by those of ordinary skill in the art that one or more suitable changes in form and details may be made therein without departing from the spirit and scope as defined by the following claims and equivalents thereof.

What is claimed is:

1. A display apparatus comprising:
a first semiconductor layer on a substrate;
a first gate insulating layer covering the first semiconductor layer;
a first gate layer on the first gate insulating layer;
a first interlayer insulating layer covering the first gate layer;
a second gate layer on the first interlayer insulating layer;
a second gate insulating layer covering the second gate layer;
a second semiconductor layer on the second gate insulating layer;
a third gate insulating layer covering the second semiconductor layer;
a third gate layer on the third gate insulating layer;
a second interlayer insulating layer covering the third gate layer;
a first connection electrode layer on the second interlayer insulating layer; and
a lower connection electrode layer between the second gate insulating layer and the second semiconductor layer and comprising at least one of a first lower connection electrode or a second lower connection electrode,
wherein the first lower connection electrode is in contact with the first semiconductor layer through a contact hole in the first gate insulating layer, the first interlayer insulating layer, and the second gate insulating layer, and the second lower connection electrode is in contact with the second gate layer through a contact hole in the second gate insulating layer.

2. The display apparatus of claim 1, wherein the lower connection electrode layer is in direct contact with the second semiconductor layer.

3. The display apparatus of claim 2, wherein the second semiconductor layer covers at least a portion of the lower connection electrode layer.

4. The display apparatus of claim 3, wherein the third gate insulating layer covers the second semiconductor layer and the lower connection electrode layer.

5. The display apparatus of claim 2, wherein the first lower connection electrode is electrically connected to the second semiconductor layer and the first semiconductor layer.

6. The display apparatus of claim 2, wherein the second lower connection electrode is electrically connected to the second semiconductor layer and the second gate layer.

7. The display apparatus of claim 1, wherein the first connection electrode layer comprises a connection electrode that is in contact with the second semiconductor layer through a contact hole in the third gate insulating layer and the second interlayer insulating layer.

8. The display apparatus of claim 7, wherein the connection electrode is electrically connected to the second semiconductor layer.

9. The display apparatus of claim 8, wherein the connection electrode is in contact with the first gate layer through a contact hole in the first interlayer insulating layer, the second gate insulating layer, the third gate insulating layer, and the second interlayer insulating layer.

10. The display apparatus of claim 1, wherein the first semiconductor layer comprises a silicon semiconductor, and the second semiconductor layer comprises an oxide semiconductor.

11. A display apparatus comprising:
a first semiconductor layer on a substrate;
a first gate insulating layer covering the first semiconductor layer;
a first gate layer on the first gate insulating layer;
a first interlayer insulating layer covering the first gate layer;
a second gate layer on the first interlayer insulating layer;
a second gate insulating layer covering the second gate layer;
a second semiconductor layer on the second gate insulating layer;
a third gate insulating layer covering the second semiconductor layer;
a third gate layer on the third gate insulating layer;
a second interlayer insulating layer covering the third gate layer;
a first connection electrode layer on the second interlayer insulating layer; and
a lower connection electrode layer between the second gate insulating layer and the second semiconductor layer and comprising a lower connection electrode,
wherein the lower connection electrode is in contact with the first gate layer through a contact hole in the first interlayer insulating layer and the second interlayer insulating layer.

12. The display apparatus of claim 11, wherein the lower connection electrode layer is in direct contact with the second semiconductor layer.

13. The display apparatus of claim 12, wherein the second semiconductor layer covers at least a portion of the lower connection electrode layer.

14. The display apparatus of claim 13, wherein the third gate insulating layer covers the second semiconductor layer and the lower connection electrode layer.

15. The display apparatus of claim 12, wherein the lower connection electrode is electrically connected to the second semiconductor layer and the first gate layer.

16. The display apparatus of claim 11, wherein the first connection electrode layer comprises a first connection electrode and a second connection electrode that are in contact with the second semiconductor layer through contact holes in the third gate insulating layer and the second interlayer insulating layer.

17. The display apparatus of claim 16, wherein the first connection electrode and the second connection electrode are electrically connected to the second semiconductor layer.

18. The display apparatus of claim 16, wherein the first connection electrode is in contact with the first semiconductor layer through a contact hole in the first gate insulating layer, the first interlayer insulating layer, the second gate insulating layer, the third gate insulating layer, and the second interlayer insulating layer.

19. The display apparatus of claim 16, wherein the second connection electrode is in contact with the second gate layer through a contact hole in the second gate insulating layer, the third gate insulating layer, and the second interlayer insulating layer.

20. The display apparatus of claim 11, wherein the first semiconductor layer comprises a silicon semiconductor, and the second semiconductor layer comprises an oxide semiconductor.

21. An electronic apparatus including the display apparatus of claim 1.
